(19) United States
(12) Patent Application Publication
(10) Pub. No.: US 2025/0364414 A1
(43) Pub. Date: Nov. 27, 2025

(54) SEMICONDUCTOR MEMORY DEVICE

(71) Applicant: Samsung Electronics Co., Ltd., Suwon-si (KR)

(72) Inventor: Jongin Kang, Suwon-si (KR)

(21) Appl. No.: 18/989,286

(22) Filed: Dec. 20, 2024

(30) Foreign Application Priority Data
May 24, 2024 (KR) 10-2024-0067674

(51) Int. Cl. H01L 23/528; H01L 23/532; H10B 12/00

(52) U.S. Cl. CPC H01L 23/5283; H01L 23/5329; H10B 12/482; H10B 12/485; H10B 12/488

(57) ABSTRACT

A semiconductor memory device may include a substrate, a first device isolation pattern and a second device isolation pattern having different widths from each other in a first direction, a first active pattern between the first device isolation pattern and the second device isolation pattern, and a word line that extends in the first direction and is on the first active pattern, where a first line that extends in a second direction and intersects an uppermost portion of the first active pattern, where the first line is spaced apart from the first device isolation pattern in the first direction by a first distance, where the first line is spaced apart from the second device isolation pattern in the first direction by a second distance, and where the first distance is less than the second distance.

### ROSS-REFERENCE TO RELATED APPLICATIONS

This U.S. non-provisional patent application claims priority under 35 U.S.C. § 119 to Korean Patent Application No. 10-2024-0067674, filed on May 24, 2024, in the Korean Intellectual Property Office, the entire contents of which are hereby incorporated by reference.

### TECHNICAL FIELD

The present disclosure relates to a semiconductor device, and in particular, to a semiconductor memory device.

### BACKGROUND

Due to their small-sized, multifunctional, and/or low-cost characteristics, semiconductor devices are being esteemed as desirable elements in the electronics industry. The semiconductor devices are classified into a semiconductor memory device for storing data, a semiconductor logic device for processing data, and a hybrid semiconductor device including both of memory and logic elements.

Due to the recent increasing demand for electronic devices with a fast speed and/or low power consumption, the semiconductor device may demand a fast operating speed and/or a low operating voltage. To satisfy the demand, it is desirable to increase an integration density of the semiconductor device. As the integration density of the semiconductor device increases, the electrical and reliability characteristics of the semiconductor device may be deteriorated. Accordingly, many studies are being conducted to improve the electrical and reliability characteristics of the semiconductor device.

### SUMMARY

An embodiment of the present disclosure provides a semiconductor memory device with improved electrical and reliability characteristics.

According to embodiments of the present disclosure, a semiconductor memory device may include a substrate, a first device isolation pattern and a second device isolation pattern having different widths from each other in a first direction that is parallel to a bottom surface of the substrate, a first active pattern between the first device isolation pattern and the second device isolation pattern, and a word line that extends in the first direction and is on the first active pattern, where a first line extends in a second direction that is perpendicular to the bottom surface of the substrate, where the first line intersects an uppermost portion of the first active pattern, where the first line is spaced apart from the first device isolation pattern in the first direction by a first distance, where the first line is spaced apart from the second device isolation pattern in the first direction by a second distance, and where the first distance is less than the second distance.

According to embodiments of the present disclosure, a semiconductor memory device may include a substrate including a first active pattern, a first device isolation pattern and a second device isolation pattern having different widths from each other in a first direction that is parallel to a bottom surface of the substrate, where the first active pattern is on the substrate and between the first device isolation pattern and the second device isolation pattern, and a word line that extends in the first direction and is on the first active pattern, where the first active pattern includes a first side surface and a second side surface, where the first side surface is adjacent to the first device isolation pattern, where the second side surface is adjacent to the second device isolation pattern, and where an absolute value of a mean slope of the first side surface is greater than an absolute value of a mean slope of the second side surface.

According to embodiments of the present disclosure, a semiconductor memory device may include a substrate that includes a cell region and a boundary region, active patterns on the cell region of the substrate, where the active patterns include a first active pattern and a second active pattern that are adjacent to each other, a first device isolation pattern and a second device isolation pattern that are on the substrate and have different widths from each other in a first direction that is parallel to a bottom surface of the substrate, where the first active pattern is between the first device isolation pattern and the second device isolation pattern, word lines that extend in the first direction and are on the first active pattern, bit lines that intersect the word lines and are on the substrate, bit line capping patterns that are respectively on the bit lines, storage node contacts between adjacent ones of the bit lines, landing pads that are respectively on the bit line capping patterns and the storage node contacts and are electrically connected to respective ones of the storage node contacts, and a capacitor that is on and electrically connected to one of the landing pads, where a distance between an uppermost portion of the first active pattern and the first device isolation pattern in the first direction is less than a distance between the uppermost portion of the first active pattern and second device isolation pattern in the first direction.

### BRIEF DESCRIPTION OF THE DRAWINGS

FIG. 1 is a block diagram illustrating a semiconductor memory device according to embodiments of the present disclosure.

FIG. 2 is a plan view illustrating a portion (e.g., ‘P1’ of FIG. 1) of a semiconductor memory device according to embodiments of the present disclosure.

FIGS. 3A, 3B, 3C, and 3D are sectional views taken along lines A-A′, B-B′, C-C′, and D-D′ of FIG. 2.

FIG. 4 is an enlarged sectional view illustrating a portion ‘M’ of FIG. 3B.

FIGS. 5, 6A, 6B, 6C, 6D, 7A, 7B, 8A, 8B, 9, 10A, 10B, 11A, 11B, 12A, 12B, 13, 14A, and 14B are sectional views illustrating a method of fabricating a semiconductor memory device, according to embodiments of the present disclosure.

FIG. 15A is a sectional view illustrating a semiconductor memory device according to embodiments of the present disclosure, taken along a line B-B′ of FIG. 2.

FIG. 15B is an enlarged sectional view illustrating a portion ‘N’ of FIG. 15A.

FIGS. 16, 17, and 18 are sectional views illustrating a method of fabricating a semiconductor memory device, according to embodiments of the present disclosure.

FIG. 19 is a plan view illustrating a portion (e.g., ‘P2’ of FIG. 1) of a semiconductor memory device according to embodiments of the present disclosure.

FIGS. 20A to 20B are sectional views taken along lines E-E′ and F-F′ of FIG. 19.

FIG. 21 is a sectional view illustrating a method of fabricating a semiconductor memory device according to embodiments of the present disclosure, taken along a line E-E′ of FIG. 19.

FIGS. 22A, 22B, 23, 24A, 24B, 25, 26A, and 26B are sectional views illustrating a method of fabricating a semiconductor memory device, according to embodiments of the present disclosure.

### DETAILED DESCRIPTION

Example embodiments of the present disclosure will now be described more fully with reference to the accompanying drawings, in which example embodiments are shown.

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items.

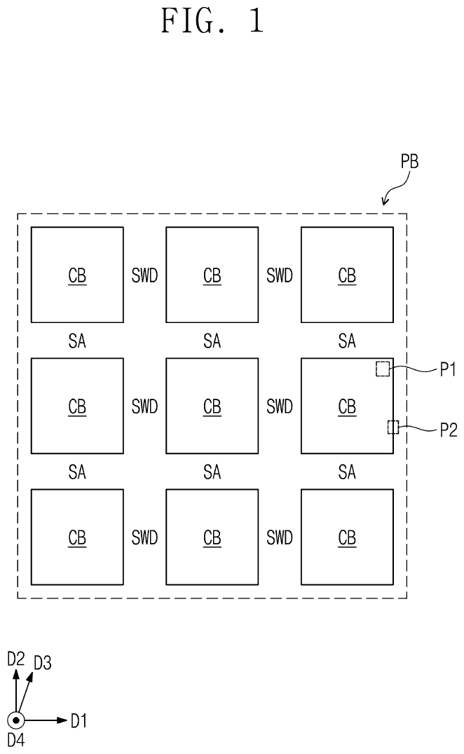

FIG. 1 is a block diagram illustrating a semiconductor memory device according to embodiments of the present disclosure.

Referring to FIG. 1, a semiconductor memory device may include cell blocks CB and a peripheral block PB around each of the cell blocks CB. Each of the cell blocks CB may include a cell circuit, such as a memory integrated circuit. The peripheral block PB may include various peripheral circuits, which are used to operate the cell circuit, and the peripheral circuits may be electrically connected to the cell circuit.

The peripheral block PB may include sense amplifier circuits SA and sub-word line driver circuits SWD. In some embodiments, the sense amplifier circuits SA may be provided to face each other, with the cell blocks CB interposed therebetween, and the sub-word line driver circuits SWD may be provided to face each other, with the cell blocks CB interposed therebetween. The peripheral block PB may further include power and ground driver circuits for driving a sense amplifier, but the present disclosure is not limited to this example.

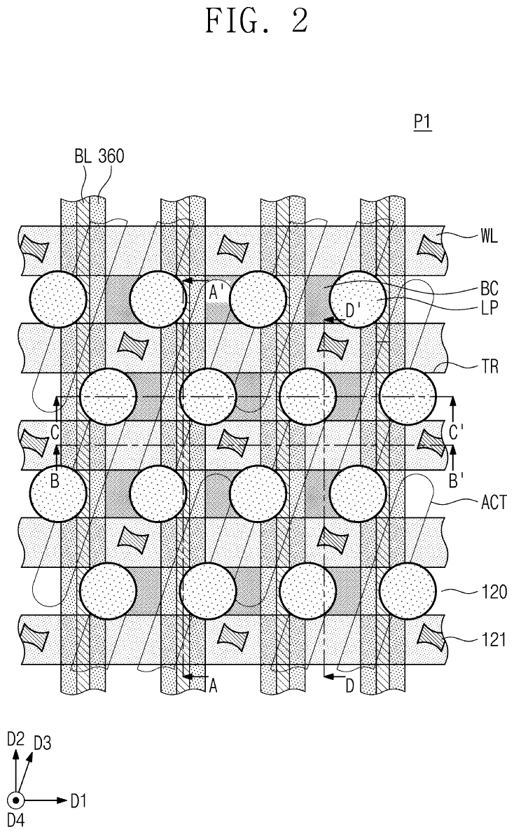

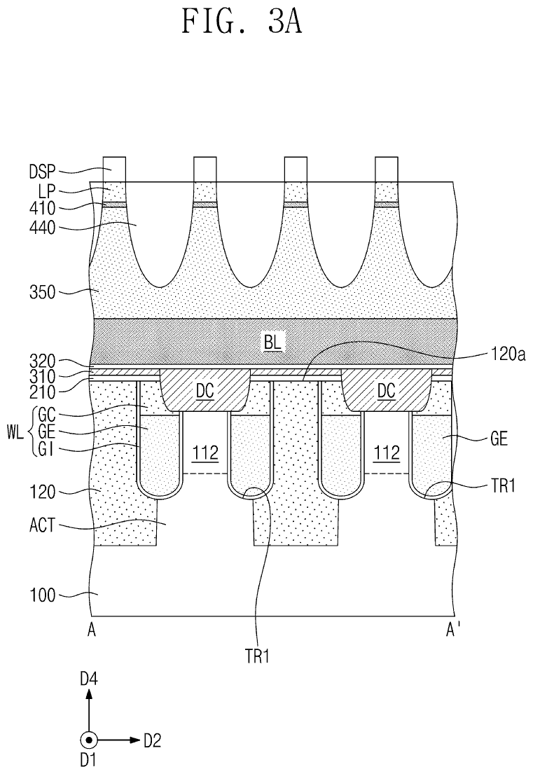

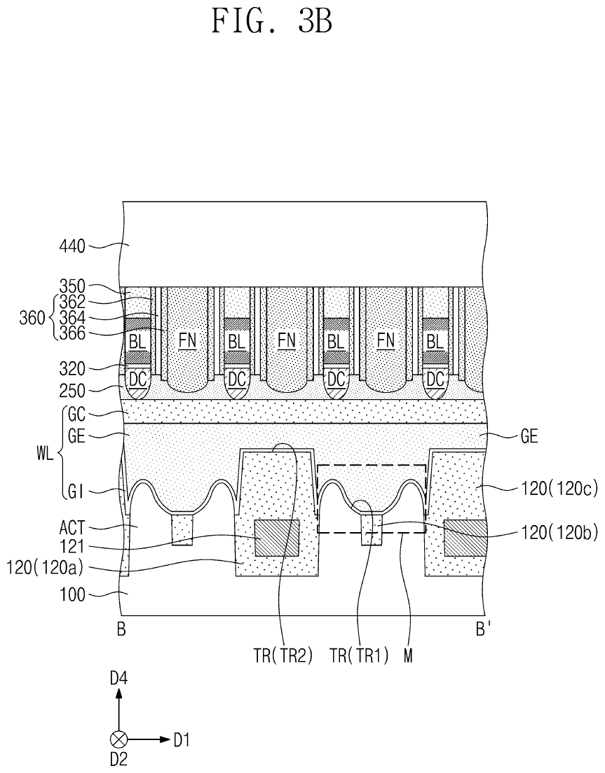

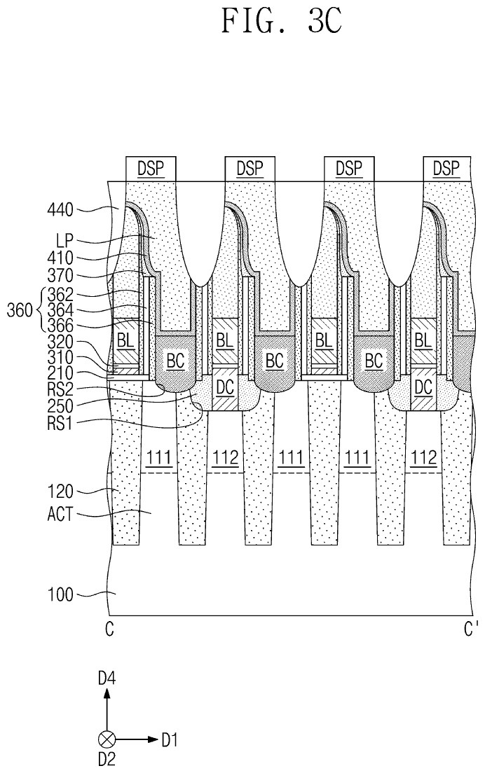

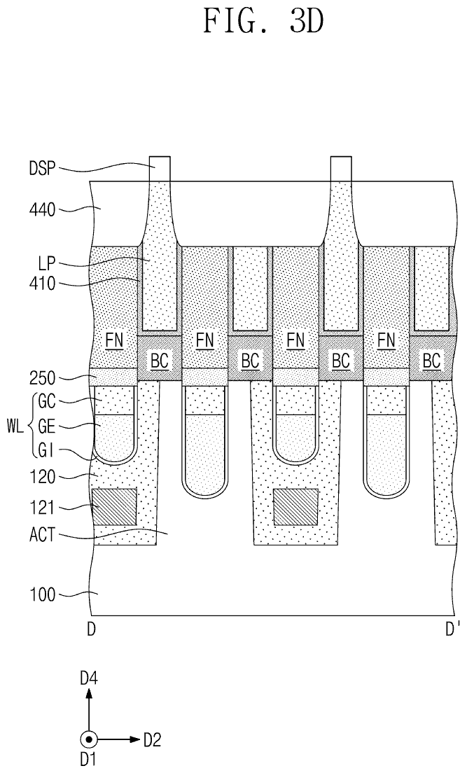

FIG. 2 is a plan view illustrating a semiconductor memory device according to embodiments of the present disclosure and corresponding to a portion ‘P1’ of FIG. 1. FIGS. 3A to 3D are sectional views illustrating a semiconductor memory device according to embodiments of the present disclosure, taken along lines A-A′, B-B′, C-C′, and D-D′, respectively, of FIG. 2.

Referring to FIGS. 2 to 3D, a substrate 100 may be provided. The substrate 100 may be a semiconductor substrate (e.g., a silicon wafer, a germanium wafer, or a silicon-germanium wafer). The substrate 100 may include a cell region on the cell blocks CB.

A device isolation pattern 120 may be disposed on the substrate 100 to define active patterns ACT. The active patterns ACT may be provided on the cell blocks CB of FIG. 1. The active patterns ACT may be spaced apart from each other in a first direction D1 and a second direction D2, which are non-parallel (e.g., perpendicular) to each other. The first direction D1 and the second direction D2 may be parallel to a bottom surface of the substrate 100. The active patterns ACT may be bar-shaped or island-shaped patterns, which are spaced apart from each other and are elongated in a third direction D3. The third direction D3 may be parallel to the bottom surface of the substrate 100 and may be non-parallel to the first and second directions D1 and D2.

The active patterns ACT may be a protruding pattern that extends in a fourth direction D4, which is perpendicular to the bottom surface of the substrate 100. In some embodiments, the device isolation pattern 120 may be disposed in the substrate 100, and the active patterns ACT may be portions of the substrate 100 enclosed by the device isolation pattern 120. For the sake of convenience in explanation, the term “substrate 100” may refer to the remaining portion of the substrate 100, excluding the active patterns ACT, unless otherwise stated.

The device isolation pattern 120 may be formed of or include at least one of insulating materials (e.g., silicon oxide, silicon nitride, or combinations thereof). The device isolation pattern 120 may be a single layer, which is made of a single material, or a composite layer including two or more materials. In the present specification, each of the expressions of “A or B”, “at least one of A and B”, “at least one of A or B”, “A, B, or C”, “at least one of A, B, and C”, and “at least one of A, B, or C” may be used to represent one of the elements enumerated in the expression or any possible combination of the enumerated elements.

Each of the active patterns ACT may include a pair of edge portions 111 and a center portion 112. The pair of edge portions 111 may be opposite end portions of the active pattern ACT in the third direction D3. The center portion 112 may be a portion of the active pattern ACT, which is placed between a pair of the edge portions 111, and in detail, it may be a portion of the active pattern ACT, which is placed between a pair of word lines WL to be described below. The pair of edge portions 111 and/or the center portion 112 may be doped with impurities to have an n-type or p-type conductivity.

The word line WL may be disposed to cross or intersect the active patterns ACT. As an example, the word line WL may cross the active patterns ACT and the device isolation pattern 120 in the first direction D1. In some embodiments, a plurality of word lines WL may be provided. The word lines WL may be spaced apart from each other in the second direction D2. In some embodiments, the pair of the word lines WL, which are adjacent to each other in the second direction D2, may be provided to cross or intersect the active pattern ACT.

The word line WL may be disposed in a trench region TR, which is formed to cross or intersect the active patterns ACT and the device isolation pattern 120. The trench region TR may extend in the first direction D1. The trench region TR may include a first trench region TR1 and a second trench region TR2. A bottom surface of the first trench region TR1 may be disposed at a level higher than a bottom surface of the second trench region TR2 in the fourth direction D4. Here, the term “level” may be defined as a height measured from the bottom surface of the substrate 100. The first trench region TR1 may be disposed on the active patterns ACT, and the second trench region TR2 may be disposed on the device isolation pattern 120.

Each of the word lines WL may include a gate electrode GE, a gate insulating pattern GI, and a gate capping pattern GC. The gate electrode GE may be disposed to cross or intersect the active pattern ACT and the device isolation pattern 120 in the first direction D1. The gate insulating pattern GI may be interposed between the gate electrode GE and the active patterns ACT and between the gate electrode GE and the device isolation pattern 120. The gate capping pattern GC may be provided on the gate electrode GE to cover or overlap a top surface of the gate electrode GE.

As an example, the gate electrode GE may be formed of or include at least one of metallic materials (e.g., Ti, Mo, W, Cu, Al, Ta, Ru, and Ir), metal nitride materials (e.g., nitrides of Ti, Mo, W, Cu, Al, Ta, Ru, and Ir), or combinations thereof. In some embodiments, the gate electrode GE may be formed of a single material. In some embodiments, the gate electrode GE may include two or more materials.

The gate insulating pattern GI may conformally cover or overlap an inner surface of the trench region TR. In some embodiments, the gate insulating pattern GI may extend into spaces between the gate capping pattern GC and the active pattern ACT and between the gate capping pattern GC and the device isolation pattern 120. The gate insulating pattern GI may be formed of or include at least one of silicon oxide, high-k dielectric materials, or combinations thereof. The gate capping pattern GC may fill or be in an upper portion of the trench region TR. The gate capping pattern GC may be formed of or include silicon nitride.

A buffer pattern 210 may be disposed on the substrate 100. The buffer pattern 210 may cover or overlap the active patterns ACT, the device isolation pattern 120, and the word lines WL. In some embodiments, the buffer pattern 210 may be formed of or include at least one of silicon oxide, silicon nitride, silicon oxynitride, or combinations thereof. The buffer pattern 210 may be a single layer, which is made of a single material, or a composite layer including two or more materials.

A bit line contact DC may be provided on each of the active patterns ACT, and in an embodiment, a plurality of bit line contacts DC may be provided. The bit line contacts DC may be connected to the center portions 112 of the active patterns ACT, respectively. In the present specification, the expression “A is connected to B” may be used to not only represent “A is in contact with B” but also represent that “A is electrically connected to B” although they are not in physical contact with each other. The bit line contacts DC may be spaced apart from each other in the first and second directions D1 and D2. The bit line contact DC may be interposed between each of the active patterns ACT and a corresponding one of bit lines BL, which will be described below. Each of the bit line contacts DC may connect a corresponding one of the bit lines BL to the center portion 112 of a corresponding one of the active patterns ACT.

The bit line contacts DC may be disposed in first recess regions RS1, respectively. The first recess regions RS1 may be provided in upper portions of the active patterns ACT and an upper portion of the device isolation pattern 120, which is adjacent to the upper portions of the active patterns ACT. The first recess regions RS1 may be spaced apart from each other in the first and second directions D1 and D2.

A gapfill insulating pattern 250 may fill or be in each of the first recess regions RS1. The gapfill insulating pattern 250 may fill or be in an inner space of the first recess region RS1. As an example, the gapfill insulating pattern 250 may cover or overlap an inner surface of the first recess region RS1 and at least a portion of a side surface of the bit line contact DC (e.g., in the first recess region RS1). The gapfill insulating pattern 250 may be formed of or include at least one of silicon oxide, silicon nitride, or combinations thereof. The gapfill insulating pattern 250 may be a single layer, which is made of a single material, or a composite layer including two or more materials.

The bit line BL may be provided on the bit line contact DC. The bit line BL may extend in the second direction D2. The bit line BL may be disposed on the bit line contacts DC, which are arranged in the second direction D2 to form a line. In some embodiments, a plurality of bit lines BL may be provided. The bit lines BL may be spaced apart from each other in the first direction D1. The bit line BL may include a metallic material. For example, the bit line BL may be formed of or include at least one of tungsten, rubidium, molybdenum, titanium, or combinations thereof.

A polysilicon pattern 310 may be provided between the bit line BL and the buffer pattern 210 and between the bit line contacts DC, which are adjacent to each other in the second direction D2. In some embodiments, a plurality of polysilicon patterns 310 may be provided. As an example, the polysilicon patterns 310 may be spaced apart from each other in the first direction D1 and the second direction D2. A top surface of the polysilicon pattern 310 may be located at substantially the same height as a top surface of the bit line contact DC relative to the bottom surface of the substrate 100 in the fourth direction D4 and may be coplanar with the top surface of the bit line contact DC. The polysilicon pattern 310 may be formed of or include doped polysilicon.

A first barrier pattern 320 may be provided between the bit line BL and the bit line contact DC and between the bit line BL and the polysilicon pattern 310. The first barrier pattern 320 may extend along the bit lines BL or in the second direction D2. In some embodiments, a plurality of first barrier patterns 320 may be provided. The first barrier pattern 320 may be spaced apart from each other in the first direction D1. The first barrier pattern 320 may be formed of or include at least one of conductive metal nitride materials (e.g., titanium nitride and tantalum nitride). A first ohmic pattern (not shown) may be additionally interposed between the bit line BL and the bit line contact DC and between the bit line BL and the polysilicon pattern 310. The first ohmic pattern may be formed of or include at least one of metal silicide materials.

A bit line capping pattern 350 may be provided on a top surface of the bit line BL. On the top surface of the bit line BL, the bit line capping pattern 350 may extend in the second direction D2. In some embodiments, a plurality of bit line capping patterns 350 may be provided. The bit line capping patterns 350 may be spaced apart from each other in the first direction D1. The bit line capping pattern 350 may vertically overlap the bit line BL. The bit line capping pattern 350 may be composed of a single layer or a plurality of layers.

A bit line spacer 360 may be provided on a side surface of the bit line BL and a side surface of the bit line capping pattern 350. The bit line spacer 360 may cover or overlap the side surface of the bit line BL and the side surface of the bit line capping pattern 350. The bit line spacer 360 on the side surface of the bit line BL may extend in the second direction D2. In some embodiments, a plurality of bit line spacers 360 may be provided. The bit line spacers 360 may be spaced apart from each other in the first direction D1.

Each of the bit line spacers 360 may include a plurality of spacers. As an example, each of the bit line spacers 360 may include a first spacer 362, a second spacer 364, and a third spacer 366. The third spacer 366 may be provided on the side surface of the bit line BL and the side surface of the bit line capping pattern 350. The first spacer 362 may be interposed between the bit line BL and the third spacer 366 and between the bit line capping pattern 350 and the third spacer 366. The second spacer 364 may be interposed between the first spacer 362 and the third spacer 366. In some embodiments, each of the first to third spacers 362, 364, and 366 may be independently formed of or include at least one of silicon nitride, silicon oxide, silicon oxynitride, or combinations thereof. As another example, the second spacer 364 may include an air gap separating the first and third spacers 362 and 366 from each other.

A capping spacer 370 may be placed on the bit line spacer 360. The capping spacer 370 may cover or overlap an upper portion of the side surface of the bit line spacer 360. In some embodiments, the capping spacer 370 may be formed of or include silicon nitride.

A storage node contact BC may be provided between adjacent ones of the bit lines BL. As an example, the storage node contact BC may be interposed between adjacent ones of the bit line spacers 360. In some embodiments, a plurality of storage node contacts BC may be provided. The storage node contacts BC may be spaced apart from each other in the first and second directions D1 and D2. The storage node contacts BC may be spaced apart from each other in the second direction D2 by fence patterns FN, which are provided on the word lines WL. The fence pattern FN may be provided between adjacent ones of the bit lines BL. In some embodiments, a plurality of fence patterns FN may be provided. The fence patterns FN may be spaced apart from each other in the first and second directions D1 and D2. The fence patterns FN, which are adjacent to each other in the first direction D1, may be spaced apart from each other, with the bit line BL interposed therebetween. The fence patterns FN, which are adjacent to each other in the second direction D2, may be spaced apart from each other, with the storage node contact BC interposed between. In some embodiments, the fence patterns FN may be formed of or include silicon nitride.

The storage node contact BC may fill or be in a second recess region RS2, which is provided on the edge portion 111 of the active pattern ACT. The storage node contact BC may be connected to the edge portion 111. The storage node contact BC may be formed of or include at least one of doped or undoped polysilicon, metallic materials, or combinations thereof.

A second barrier pattern 410 may conformally cover or overlap the bit line spacer 360, the fence pattern FN, and the storage node contact BC. The second barrier pattern 410 may be formed of or include at least one of metal nitride materials (e.g., titanium nitride and tantalum nitride). A second ohmic pattern (not shown) may be further interposed between the second barrier pattern 410 and the storage node contact BC. The second ohmic pattern may be formed of or include at least one of metal silicide materials.

A landing pad LP may be provided on the storage node contact BC. In an embodiment, a plurality of landing pads LP may be provided. The landing pads LP may be spaced apart from each other in the first and second directions D1 and D2. Each of the landing pads LP may be connected to a corresponding one of the storage node contacts BC. The landing pad LP may cover or overlap a top surface of the bit line capping pattern 350. A lower region of the landing pad LP may be vertically overlapped by the storage node contact BC. An upper region of the landing pad LP may be shifted from the lower region in the first direction D1. The landing pad LP may be formed of or include at least one of metallic materials (e.g., tungsten, titanium, and tantalum).

A filler pattern 440 may be provided to enclose or surround at least a portion of the landing pad LP. The filler pattern 440 may be interposed between adjacent ones of the landing pads LP. When viewed in a plan view, the filler pattern 440 may be provided in a mesh shape with holes, and in this case, the landing pads LP may be provided in the holes to penetrate or extend into the filler pattern 440. As an example, the filler pattern 440 may be formed of or include at least one of silicon nitride, silicon oxide, silicon oxynitride, or combinations thereof. As another example, the filler pattern 440 may include an empty space with an air layer (i.e., an air gap).

A data storage pattern DSP may be provided on the landing pad LP. A plurality of data storage patterns DSP may be provided. The data storage patterns DSP may be spaced apart from each other in the first and second directions D1 and D2. Each of the data storage patterns DSP may be connected to a corresponding one of the edge portions 111 through a corresponding one of the landing pads LP and a corresponding one of the storage node contacts BC.

In some embodiments, the data storage pattern DSP may be a capacitor including a bottom electrode, a dielectric layer, and a top electrode. In this case, the semiconductor memory device may be a dynamic random access memory (DRAM) device. As another example, the data storage pattern DSP may include a magnetic tunnel junction pattern. In this case, the semiconductor memory device may be a magnetic random access memory (MRAM) device. As other examples, the data storage pattern DSP may include a phase-change material or a variable resistance material. In this case, the semiconductor memory device may be a phase-change random access memory (PRAM) device or a resistive random access memory (ReRAM) device. However, the present disclosure is not limited to these examples, and the data storage pattern DSP may include various structures and/or materials that can be used to store data therein.

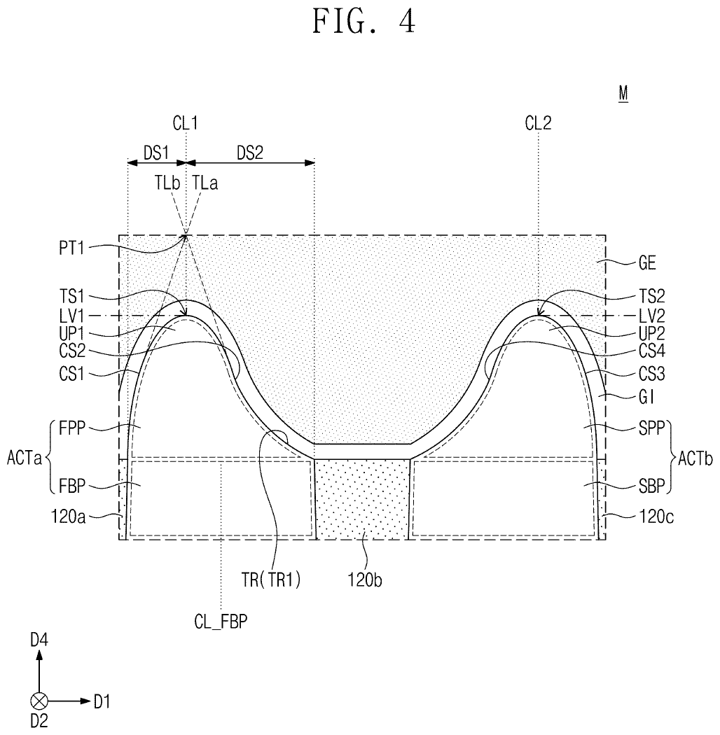

FIG. 4 is an enlarged sectional view illustrating a portion ‘M’ of FIG. 3B. The active patterns ACT and the device isolation pattern 120 will be described in more detail with reference to FIGS. 3B and 4.

The active patterns ACT may include a first active pattern ACTa and a second active pattern ACTb, which are arranged in the first direction D1. The device isolation pattern 120 may be interposed between the first active pattern ACTa and the second active pattern ACTb. In detail, the first active pattern ACTa may be provided between a first device isolation pattern 120a and a second device isolation pattern 120b. The second active pattern ACTb may be provided between the second device isolation pattern 120b and a third device isolation pattern 120c. The first active pattern ACTa may be defined by the first and second device isolation patterns 120a and 120b. The second active pattern ACTb may be defined by the second and third device isolation patterns 120b and 120c.

The first and second device isolation patterns 120a and 120b may have different widths in the first direction D1 from each other. The second and third device isolation patterns 120b and 120c may have different widths in the first direction D1 from each other. For example, the width of the first device isolation pattern 120a and the width of the third device isolation pattern 120c may be larger than the width of the second device isolation pattern 120b. The level of the bottom surface of the first device isolation pattern 120a relative to the bottom surface of the substrate 100 in the fourth direction D4 may be lower than the level of the bottom surface of the second device isolation pattern 120b relative to the bottom surface of the substrate 100 in the fourth direction D4.

The level of the highest portion of the first device isolation pattern 120a may be higher or lower than the level of the highest portion of the second device isolation pattern 120b relative to the bottom surface of the substrate 100 in the fourth direction D4. The level of the top surface of the first device isolation pattern 120a may be higher than the level of the top surface of the second device isolation pattern 120b relative to the bottom surface of the substrate 100 in the fourth direction D4. In some embodiments, the level of the top surface of the first device isolation pattern 120a may be equal to the level of the top surface of the second device isolation pattern 120b relative to the bottom surface of the substrate 100 in the fourth direction D4.

Each of the first and third device isolation patterns 120a and 120c may include a gapfill pattern 121. The gapfill pattern 121 may be buried in each of the first and third device isolation patterns 120a and 120c. The second device isolation pattern 120b may not include the gapfill pattern 121. The gapfill pattern 121 may be at least partially surrounded by each of the first and third device isolation patterns 120a and 120c. A top surface of the gapfill pattern 121 may be located at a level lower than a top surface of each of the first and third device isolation patterns 120a and 120c relative to the bottom surface of the substrate 100 in the fourth direction D4. The largest width of the gapfill pattern 121 in the first direction D1 may be smaller than the smallest width of each of the first and third device isolation patterns 120a and 120c in the first direction D1. The gapfill pattern 121 may include a different material from the first to third device isolation patterns 120a, 120b, and 120c. For example, the gapfill pattern 121 may be formed of or include silicon nitride.

The first active pattern ACTa may include a first body portion FBP and a first protruding portion FPP on the first body portion FBP. The first protruding portion FBP may be a portion of the first active pattern ACTa, which protrudes or extends in a vertical direction D4 relative to the first and second device isolation patterns 120a and 120b. A width of the first protruding portion FBP in the first direction D1 may decrease as a height in the fourth direction D4 relative to the bottom surface of the substrate 100 increases. The first protruding portion FBP of the first active pattern ACTa may include a first upper portion UP1. The first upper portion UP1 may be a portion including a top surface (or uppermost portion) TS1 of the first active pattern ACTa.

The highest level (or largest height) LV1 of the first active pattern ACTa may be lower than the highest level of the first device isolation pattern 120a relative to the bottom surface of the substrate 100 in the fourth direction D4. In detail, the top surface TS1 of the first active pattern ACTa may be located at a level that is lower than the topmost surface (or uppermost portion) of the first device isolation pattern 120a relative to the bottom surface of the substrate 100 in the fourth direction D4. The top surface TS1 of the first active pattern ACTa may be located at a level higher than the top surface of the second device isolation pattern 120b relative to the bottom surface of the substrate 100 in the fourth direction D4.

A first vertical line CL1 extending in the vertical direction D4 may be defined based on the first upper portion UP1. The top surface TS1 of the first active pattern ACTa may be located on the first vertical line CL1. In some embodiments, the first vertical line CL1 may be normal or perpendicular to the top surface TS1 of the first active pattern ACTa. The first vertical line CL1 may be a line that is defined to vertically penetrate or extend into the highest portion of the first active pattern ACTa. The first vertical line CL1 may be offset from a center line CL_FBP of the first body portion FBP in the first direction D1 or its opposite direction.

The first vertical line CL1 may be spaced apart from the first device isolation pattern 120a in the horizontal direction D1 by a first distance DS1. The first vertical line CL1 may be spaced apart from the second device isolation pattern 120b in the first direction D1 by a second distance DS2. The first distance DS1 may be a distance between the top surface of the first active pattern ACTa and the first device isolation pattern 120a in the first direction D1. The second distance DS2 may be a distance between the top surface of the first active pattern ACTa and the second device isolation pattern 120b in the first direction D1.

The first distance DS1 and the second distance DS2 may be different from each other. The first distance DS1 may be smaller than the second distance DS2. The top surface TS1 of the first active pattern ACTa may be closer to one of the first and second device isolation patterns 120a and 120b than to the other. The first active pattern ACTa may have a shape that is skewed in the first direction D1 or its opposite direction. A distance DS1 between the top surface TS1 of the first active pattern ACTa and the first device isolation pattern 120a in the first direction D1 may be smaller than a distance DS2 between the top surface TS1 of the first active pattern ACTa and the second device isolation pattern 120b in the first direction D1.

The first active pattern ACTa may include a first side surface CS1 and a second side surface CS2. The first side surface CS1 and the second side surface CS2 may be opposite to each other in the first direction D1. The first side surface CS1 may be adjacent to the first device isolation pattern 120a. The second side surface CS2 may be adjacent to the second device isolation pattern 120b. A length of the first side surface CS1 may be smaller than a length of the second side surface CS2 in the fourth direction D4. The first side surface CS1 and the second side surface CS2 may meet each other on or at the top surface TS1 of the first active pattern ACTa. The first vertical line CL1 may be defined between the first side surface CS1 and the second side surface CS2.

A slope of a tangent line of the first side surface CS1 may have a different sign from a slope of a tangent line of the second side surface CS2 relative to the bottom surface of the substrate 100 or the first direction D1. For example, the slope of the tangent line of the first side surface CS1 may have a positive sign, and the slope of the tangent line of the second side surface CS2 may have a negative sign. An absolute value of a mean slope of the first side surface CS1 may be greater than an absolute value of a mean slope of the second side surface CS2 relative to the bottom surface of the substrate 100 or the first direction D1. A mean slope of the first side surface CS1 may be a mean value of the slopes of two or more of the tangent lines of the first side surface CS1. A mean slope of the second side surface CS2 may be a mean value of the slopes of two or more of the tangent lines of the second side surface CS2.

The first side surface CS1 may include a first tangent line TLa. The second side surface CS2 may include a second tangent line TLb. A slope of the first tangent line TLa and a slope of the second tangent line TLb may have different signs from each other relative to the bottom surface of the substrate 100 or the first direction D1. The slope of the first tangent line TLa may have a positive sign, and the slope of the second tangent line TLb may have a negative sign. The first tangent line TLa and the second tangent line TLb may extend to meet at a first point PT1. The first point PT1 may be defined at a position higher than the top surface of the first active pattern ACTa relative to the bottom surface of the substrate 100 in the fourth direction D4. The first tangent line TLa, the second tangent line TLb, and the first vertical line CL1 may meet each other at the first point PT1.

The second active pattern ACTb may have the same physical and chemical properties as the first active pattern ACTa. Here, the second active pattern ACTb may have a symmetric profile to the first active pattern ACTa. The second active pattern ACTb may include a second body portion SBP and a second protruding portion SPP on the second body portion SBP. The second protruding portion SPP may be a portion of the second active pattern ACTb which protrudes or extends in the vertical direction D4 relative to the second and third device isolation patterns 120b and 120c. The second protruding portion SPP may include a second upper portion UP2. The second upper portion UP2 may be a portion including a top surface (or uppermost portion) TS2 of the second active pattern ACTb.

The highest level (or largest height) LV2 of the second active pattern ACTb may be higher than the highest level of the third device isolation pattern 120c relative to the bottom surface of the substrate 100 in the fourth direction D4. In detail, the top surface TS2 of the second active pattern ACTb may be located at a level higher than the top surface of the third device isolation pattern 120c relative to the bottom surface of the substrate 100 in the fourth direction D4. The top surface TS2 of the second active pattern ACTb may be located at a level higher than the top surface of the second device isolation pattern 120b relative to the bottom surface of the substrate 100 in the fourth direction D4.

A second vertical line CL2 extending in the vertical direction D4 may be defined based on the second upper portion UP2. The second vertical line CL2 may be located on the top surface TS2 of the second active pattern ACTb. In some embodiments, the second vertical line CL2 may be normal or perpendicular to the top surface TS2 of the second active pattern ACTb. The second vertical line CL2 may be a line that is defined to vertically penetrate or extend into the highest portion of the second active pattern ACTb.

The second vertical line CL2 may be closer to the third device isolation pattern 120c than to the second device isolation pattern 120b. In detail, a distance between the second vertical line CL2 and the second device isolation pattern 120b in the first direction D1 may be larger than a distance between the second vertical line CL2 and the third device isolation pattern 120c in the first direction D1. The second active pattern ACTb may have a shape that is skewed in the first direction D1 or its opposite direction.

The second active pattern ACTb may include a third side surface CS3 and a fourth side surface CS4. The third side surface CS3 and the fourth side surface CS4 may be opposite to each other in the first direction D1. The third side surface CS3 may be adjacent to the third device isolation pattern 120c. The fourth side surface CS4 may be adjacent to the second device isolation pattern 120b. The fourth side surface CS4 may face the third side surface CS3. A length of the third side surface CS3 may be smaller than a length of the fourth side surface CS4 in the fourth direction D4. The third side surface CS3 and the fourth side surface CS4 may meet each other on or at the top surface TS2 of the second active pattern ACTb. The second vertical line CL2 may be defined between the third side surface CS3 and the fourth side surface CS4. The third side surface CS3 and the fourth side surface CS4 may have substantially the same features as the first side surface CS1 and the second side surface CS2, respectively.

According to embodiments of the present disclosure, the first active pattern ACTa and the second active pattern ACTb may have an asymmetric profile. Each of the first and second vertical lines CL1 and CL2 may pass through or extend into a position that is skewed in a direction away from the second device isolation pattern 120b. Thus, a distance between the first active pattern ACTa and the second active pattern ACTb in the first direction D1 may be increased. Between the first active pattern ACTa and the second active pattern ACTb, the gate electrode GE may be provided over or on a wider region. As a result, both the electrical and reliability characteristics of the semiconductor memory device may be improved.

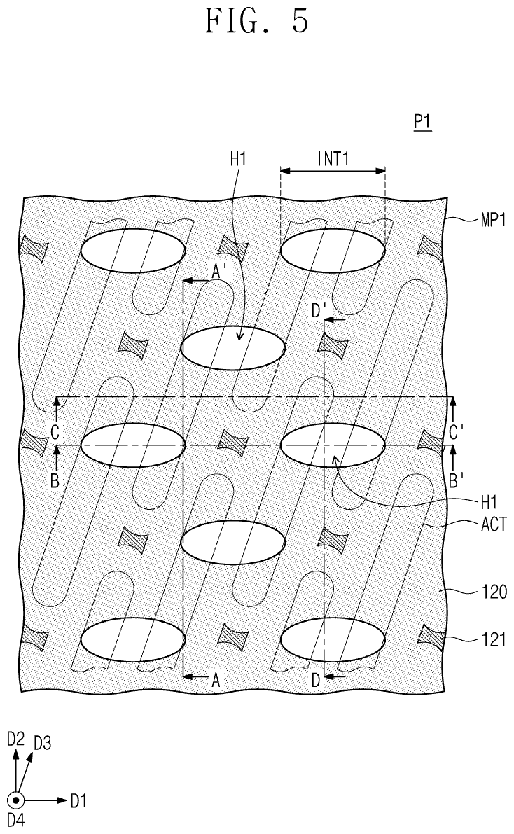

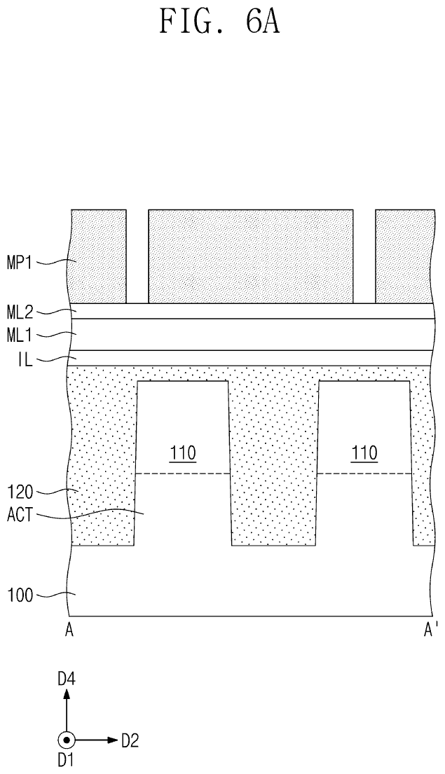

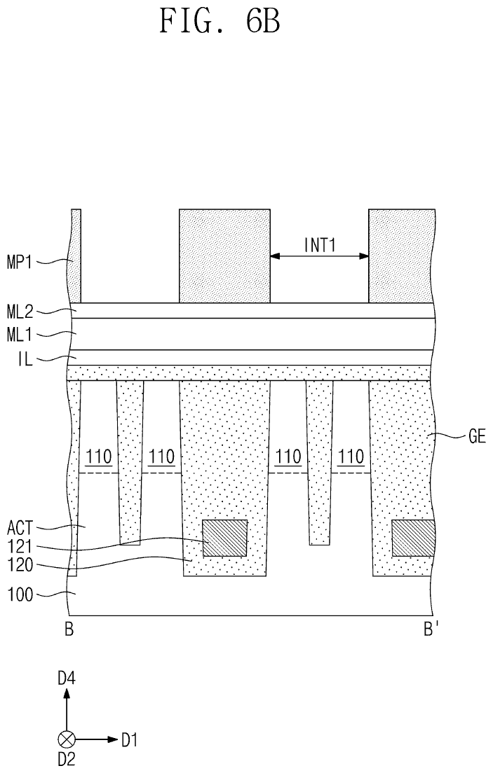

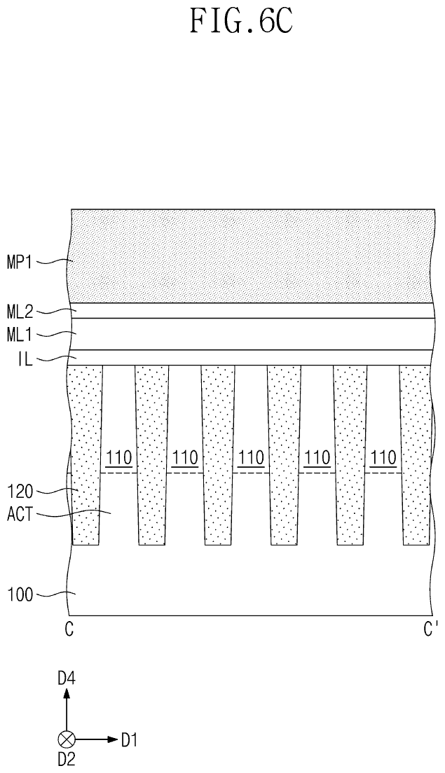

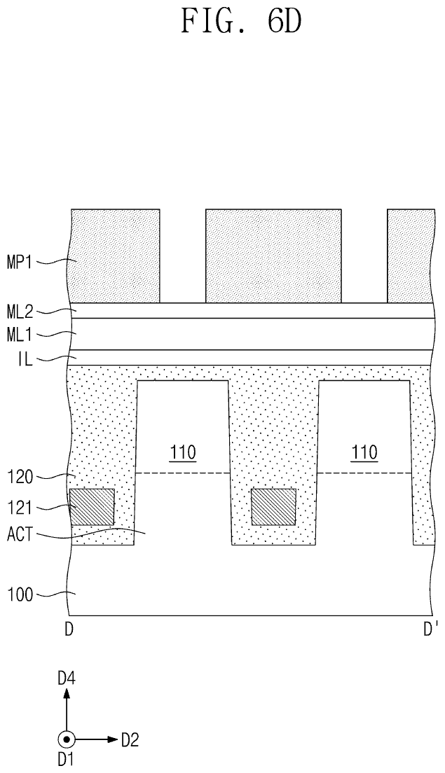

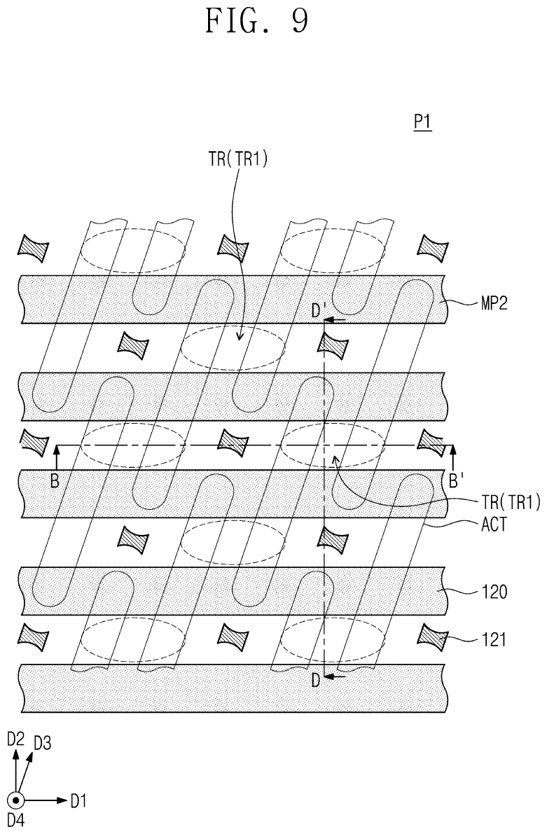

FIGS. 5 to 14B are sectional views illustrating a method of fabricating a semiconductor memory device, according to embodiments of the present disclosure. In detail, FIGS. 5 and 9 are plan views corresponding to a portion ‘P1’ of FIG. 1. FIG. 6A is a sectional view corresponding to the line A-A′ of FIG. 2. FIGS. 6B, 7A, 8A, 10A, 11A, 12A, and 14A are sectional views corresponding to the line B-B′ of FIG. 2. FIG. 6C is a sectional view corresponding to the line C-C′ of FIG. 2. FIGS. 6D, 7B, 8B, 10B, 11B, 12B, 13, and 14B are sectional views corresponding to the line D-D′ of FIG. 2. Hereinafter, a fabrication method according to embodiments of the present disclosure will be described in more detail with reference to FIGS. 5 to 14B. For concise description, a previously-described element may be identified by the same reference number without repeating an overlapping description thereof.

Referring to FIGS. 5 and 6A to 6D, the substrate 100 may be prepared. The device isolation pattern 120 may be formed to be buried in an upper portion of the substrate 100. The formation of the device isolation pattern 120 may include performing a patterning process to remove a portion of the upper portion of the substrate 100 and at least partially filling the removed region with the device isolation pattern 120. Remaining portions of the upper portion of the substrate 100, which are enclosed or at least partially surrounded by the device isolation pattern 120, may be defined as the active patterns ACT. Impurity regions may be formed in the active patterns ACT. The formation of the impurity regions may include injecting impurities into the active patterns ACT through an ion implantation process.

An insulating layer IL, a first mold layer ML1, and a second mold layer ML2 may be sequentially formed on the active patterns ACT and the device isolation pattern 120. The insulating layer IL may have an etch selectivity with respect to the first and second mold layers ML1 and ML2. In some embodiments, the first and second mold layers ML1 and ML2 may include at least one of a silicon oxide layer, a silicon nitride layer, or a metal nitride layer.

A first mask pattern MP1 may be formed on the second mold layer ML2. The first mask pattern MP1 may have an etch selectivity with respect to the second mold layer ML2. Adjacent ones of the first mask patterns MP1 may be spaced apart from each other in the first direction D1 by a first distance INT1. The first mask patterns MP1 may be formed on the gapfill pattern 121. The first mask patterns MP1 may not be formed on portions of the active patterns ACT, which are adjacent to each other. For example, the first mask patterns MP1 may not be formed on portions of the active patterns ACT, on which the word line WL will be formed (e.g., see FIG. 5).

A first hole H1 may be formed to expose the second mold layer ML2. When viewed in a plan view, the first hole H1 may have an elliptical shape. A length of a long axis of the first hole H1 in the first direction D1 may be equal to the first distance INT1. The first hole H1 may be provided to cross or intersect adjacent ones of the active patterns ACT.

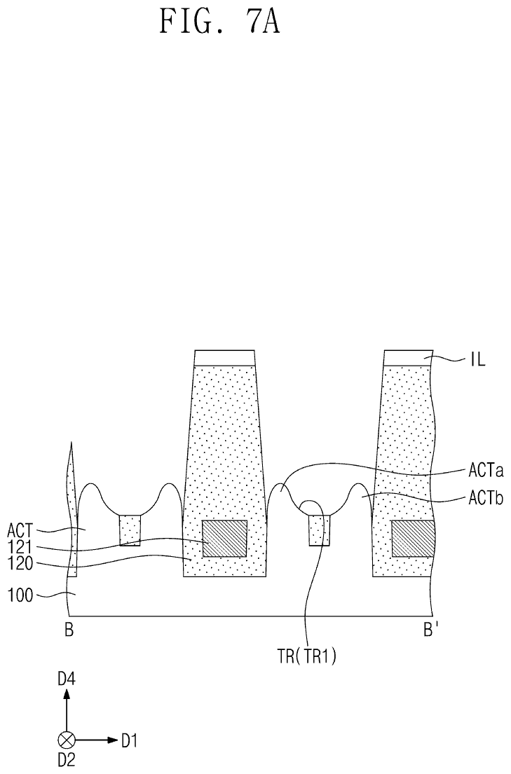

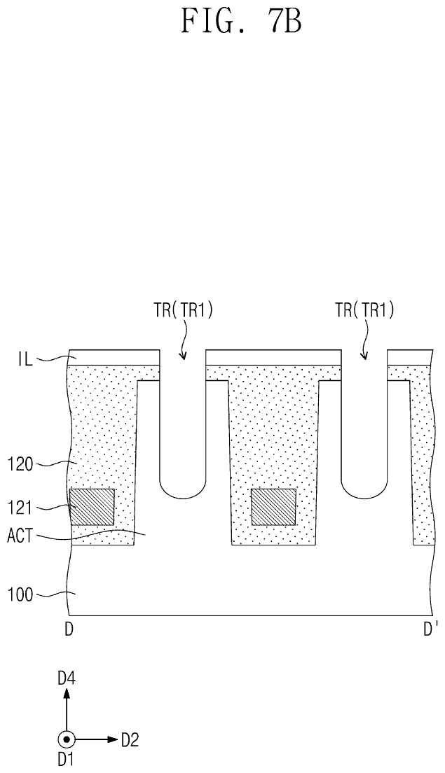

Referring to FIGS. 7A and 7B, the first and second mold layers ML1 and ML2 may be etched using the first mask pattern MP1 as an etch mask. Thereafter, the first mask pattern MP1 may be removed. The insulating layer IL, an upper portion of the device isolation pattern 120, and an upper portion of the active patterns ACT may be etched using the first and second mold layers ML1 and ML2 as an etch mask. The first trench region TR1 may be formed by the etching process. When viewed in a plan view, the first trench region TR1 may have an elliptical profile. For example, the first trench region TR1 may have an elliptical shape which has a long axis extending in the first direction D1 and a short axis extending in the second direction D2. The first trench region TR1 may be formed on a pair of the active patterns ACT, which are adjacent to each other in the first direction D1.

Due to the first trench region TR1, each of the first and second active patterns ACTa and ACTb, which are adjacent to each other in the first direction D1, may have an asymmetric profile. Owing to the first trench region TR1, the first active pattern ACTa and the second active pattern ACTb may be formed to have the shape described with reference to FIG. 4. Opposite side surfaces of the first active pattern ACTa may have different lengths from each other. An upper portion of the first active pattern ACTa may be formed to be skewed toward an unetched portion of the device isolation pattern 120 or in the opposite direction of the first direction D1. The second active pattern ACTb may be symmetric to the first active pattern ACTa.

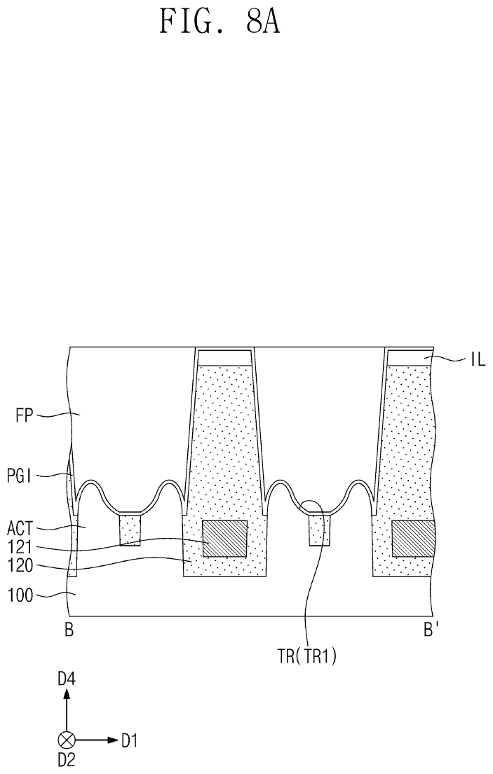

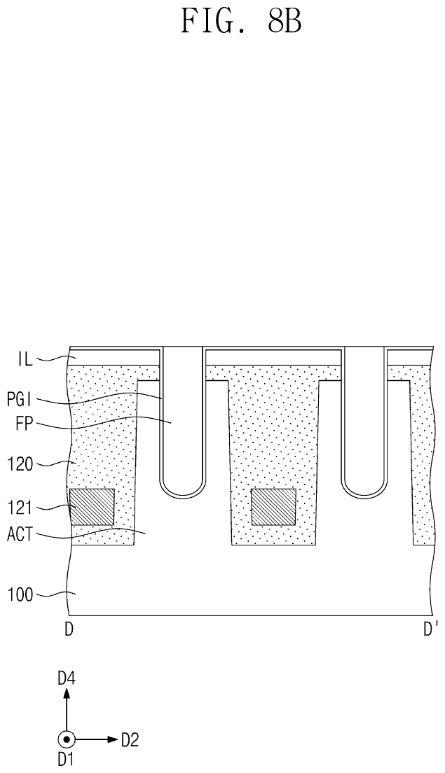

Referring to FIGS. 8A and 8B, a first preliminary gate insulating layer PGI may be conformally formed on the first trench region TR1. For example, the first preliminary gate insulating layer PGI may conformally cover or overlap inner surfaces of the first trench region TR1. The first preliminary gate insulating layer PGI may extend to cover or overlap top surfaces of the active patterns ACT and top and side surfaces of the device isolation pattern 120. The first preliminary gate insulating layer PGI may be formed by a physical vapor deposition (PVD) process, a chemical vapor deposition (CVD) process, or an atomic layer deposition (ALD) process. The first preliminary gate insulating layer PGI may be formed of or include at least one of silicon oxide, high-k dielectric materials, or combinations thereof.

A capping pattern FP may be formed in the first trench region TR1. In detail, the formation of the capping pattern FP may include forming a filling layer on the substrate 100 and performing a planarization process on the filling layer to form the capping pattern FP. The planarization of the filling layer may be performed using an etch-back process or a chemical mechanical polishing (CMP) process. A top surface of the capping pattern FP may be located at the same level as a top surface of the first preliminary gate insulating layer PGI relative to the bottom surface of the substrate 100 in the fourth direction D4. The capping pattern FP may be formed of or include at least one of silicon nitride or silicon oxide, but the present disclosure is not limited to this example.

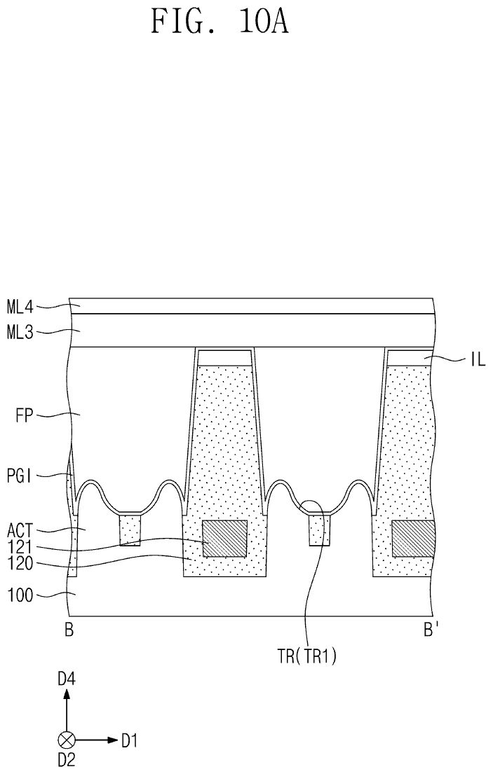

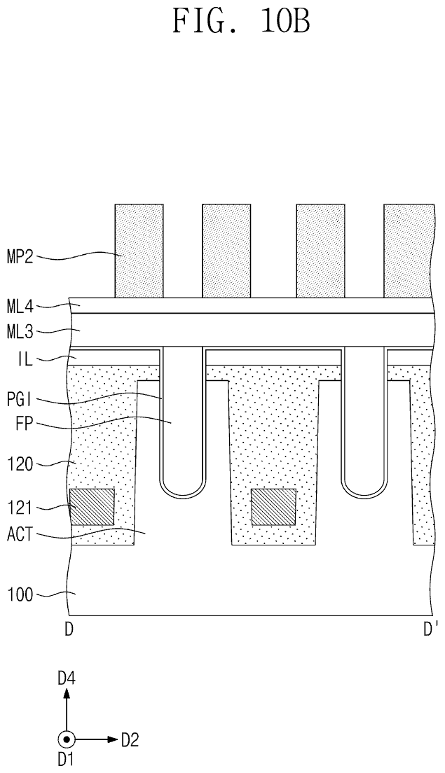

Referring to FIGS. 9, 10A, and 10B, a third mold layer ML3 and a fourth mold layer ML4 may be sequentially formed on the substrate 100. The third mold layer ML3 may cover or overlap the capping pattern FP and the first preliminary gate insulating layer PGI. The third and fourth mold layers ML3 and ML4 may be substantially the same as the first and second mold layers ML1 and ML2, respectively.

A second mask pattern MP2 may be formed on the fourth mold layer ML4. The second mask pattern MP2 may have an etch selectivity with respect to the fourth mold layer ML4. The second mask pattern MP2 may extend in the first direction D1. The second mask patterns MP2 may be spaced apart from each other in the second direction D2. The second mask pattern MP2 may not be formed on a region, on which the word lines WL will be formed.

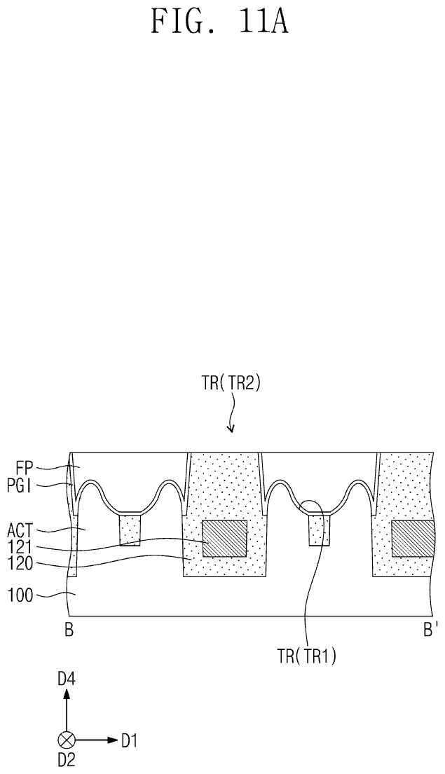

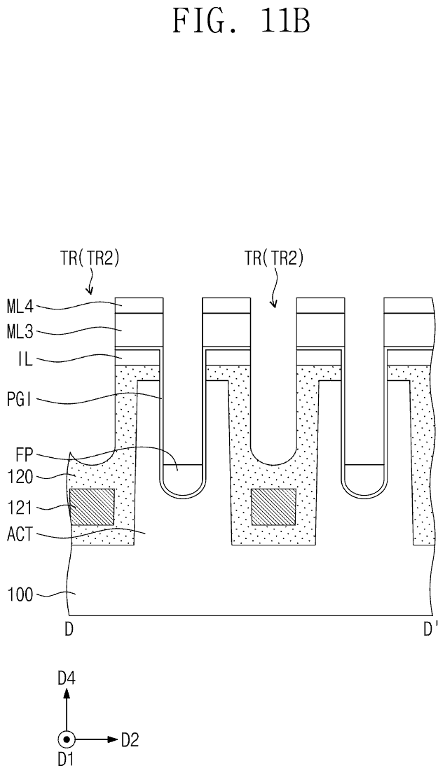

Referring to FIGS. 11A and 11B, the third mold layer ML3 and the fourth mold layer ML4 may be etched using the second mask pattern MP2 as an etch mask. Next, the second mask pattern MP2 may be removed. An upper portion of the capping pattern FP and an upper portion of the device isolation pattern 120 may be etched using the third and fourth mold layers ML3 and ML4 as an etch mask. The second trench region TR2 may be formed by the etching process.

The top surface of the capping pattern FP may be coplanar with the top surface of the device isolation pattern 120 exposed by the second trench region TR2. A depth of the second trench region TR2 may be smaller than a depth of the first trench region TR1 in the fourth direction D4. A bottom surface of the second trench region TR2 may be located at a level higher than the bottom surface of the first trench region TR1 relative to the bottom surface of the substrate 100 in the fourth direction D4. In some embodiments, the bottom surface of the first trench region TR1 may be formed at a level that is equal to or higher than the bottom surface of the second trench region TR2 relative to the bottom surface of the substrate 100 in the fourth direction D4.

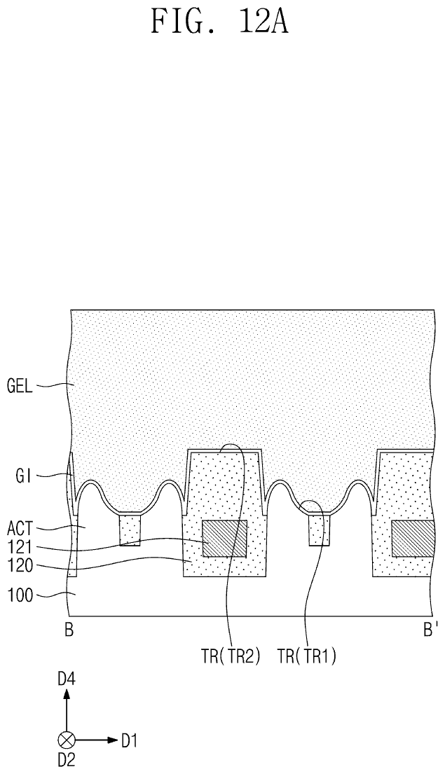

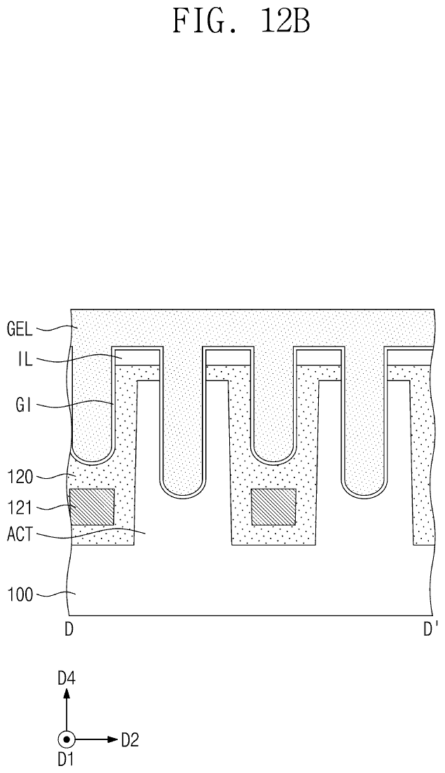

Referring to FIGS. 12A and 12B, the capping pattern FP and the first preliminary gate insulating layer PGI may be removed from the first trench region TR1. Next, the gate insulating pattern GI may be conformally formed on the substrate 100. For example, the gate insulating pattern GI may conformally cover or overlap inner surfaces of the first and second trench regions TR1 and TR2. The gate insulating pattern GI may be formed on top surfaces of the active patterns ACT and top and side surfaces of the device isolation pattern 120. The gate insulating pattern GI may be formed using a physical vapor deposition (PVD) process, a chemical vapor deposition (CVD) process, or an atomic layer deposition (ALD) process. The gate insulating pattern GI may be formed of or include at least one of silicon oxide, high-k dielectric materials, or combinations thereof.

A gate electrode layer GEL may be formed on the substrate 100. The gate electrode layer GEL may fill or be in the first and second trench regions TR1 and TR2. The gate electrode layer GEL may be formed of or include at least one of metallic materials (e.g., Ti, Mo, W, Cu, Al, Ta, Ru, and Ir), metal nitride materials (e.g., nitrides of Ti, Mo, W, Cu, Al, Ta, Ru, and Ir), or combinations thereof.

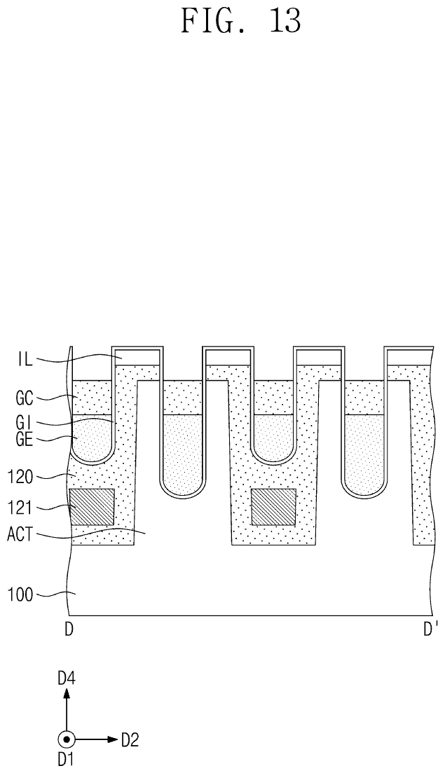

Referring to FIG. 13, an upper portion of the gate electrode layer GEL may be etched to form the gate electrode GE. The etching of the upper portion of the gate electrode layer GEL may include performing an etch-back process. The gate capping pattern GC may be formed on the gate electrode GE. The gate capping pattern GC may fill or be in each of remaining portions of the first and second trench regions TR1 and TR2. The formation of the gate capping pattern GC may include forming a gate capping layer (not shown) to fill or be in the remaining portions of the first and second trench regions TR1 and TR2 and to cover or overlap the top surfaces of the active patterns ACT and the top surface of the device isolation pattern 120 and removing an upper portion of the gate capping layer to form the gate capping patterns GC, which are spaced apart from each other.

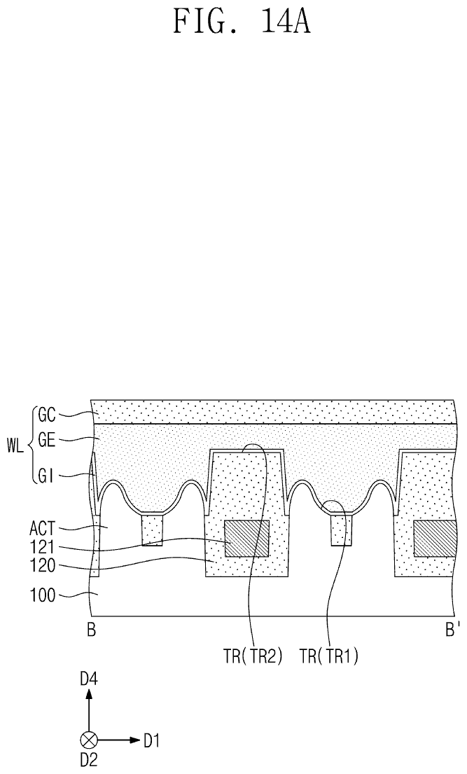

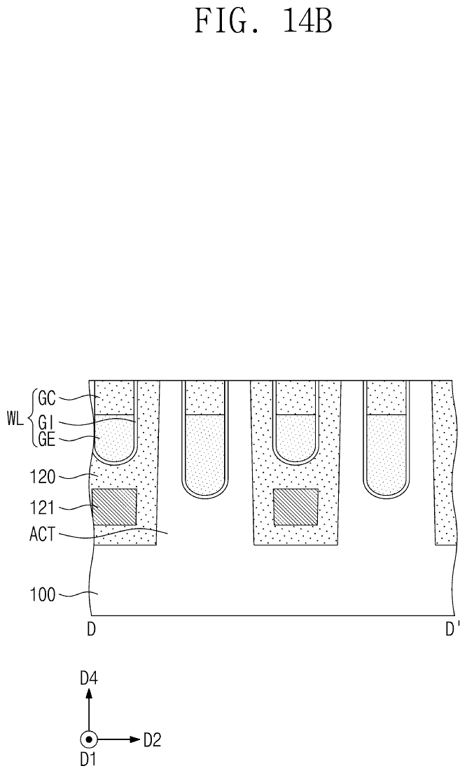

Referring to FIGS. 14A and 14B, the insulating layer IL and an upper portion of the gate insulating pattern GI may be removed by an etching process. The gate electrode GE, the gate insulating pattern GI, and the gate capping pattern GC may constitute the word line WL.

Referring back to FIGS. 3A to 3D, a buffer layer (not shown) and a poly-silicon layer (not shown) may be formed to cover or overlap the active patterns ACT and the device isolation pattern 120, and the first recess region RS1 may be formed on each of the active patterns ACT and the device isolation pattern 120. Here, the buffer layer and the poly-silicon layer may be partially removed to form the buffer pattern 210 and the polysilicon pattern 310.

The bit line contact DC, the first barrier pattern 320, the bit line BL, and the bit line capping pattern 350 may be formed on the first recess region RS1. The formation of the bit line contact DC, the first barrier pattern 320, the bit line BL, and the bit line capping pattern 350 may include forming a bit line contact layer (not shown) to fill or be in the first recess region RS1, sequentially forming a first barrier layer (not shown), a bit line layer (not shown), and a bit line capping layer (not shown) on the bit line contact layer, and etching the bit line contact layer, the first barrier layer, the bit line layer, and the bit line capping layer to form the bit line contact DC, the first barrier pattern 320, the bit line BL, and the bit line capping pattern 350. Here, a portion of the polysilicon pattern 310 may be further etched. During this process, an inner portion of the first recess region RS1 may be partially exposed to the outside. Thereafter, the gapfill insulating pattern 250 may be formed to fill or be in a remaining portion of the first recess region RS1. A first ohmic pattern (not shown) may be further formed between the bit line BL and the bit line contact DC and between the bit line BL and the polysilicon pattern 310, in a process of forming the bit line BL.

The bit line spacer 360 may be formed to cover or overlap the side surface of the bit line BL and the side surface of the bit line capping pattern 350. The formation of the bit line spacer 360 may include sequentially forming the first spacer 362, the second spacer 364, and the third spacer 366 to conformally cover or overlap the side surface of the bit line BL and the bit line capping pattern 350.

The storage node contacts BC and the fence patterns FN may be formed between adjacent ones of the bit lines BL. The storage node contacts BC and the fence patterns FN may be alternately arranged in the second direction D2. Each of the storage node contacts BC may be formed to fill or be in the second recess region RS2 and may be electrically connected to a corresponding edge portion 111 of the active pattern ACT in the second recess region RS2. The fence patterns FN may be formed at positions that are vertically overlapped by the word lines WL. In some embodiments, the storage node contacts BC may be formed first, and then the fence patterns FN may be formed between the storage node contacts BC. In some embodiments, the fence patterns FN may be formed first, and then the storage node contacts BC may be formed between the fence patterns FN.

An upper portion of the bit line spacer 360 may be partially removed during the formation of the storage node contacts BC. In this case, the capping spacer 370 may be additionally formed in a region, which is formed by removing the bit line spacer 360. Thereafter, the second barrier pattern 410 may be formed to conformally cover or overlap the bit line spacer 360, the capping spacer 370, and the storage node contacts BC.

The landing pads LP may be formed on the storage node contacts BC. The formation of the landing pads LP may include sequentially forming a landing pad layer (not shown) and mask patterns (not shown) to cover or overlap the top surfaces of the storage node contacts BC and performing an anisotropic etching process using the mask patterns as an etch mask on the landing pad layer to form a plurality of landing pads LP that are separated from each other. Additionally, the second barrier pattern 410, the bit line spacer 360, and the bit line capping pattern 350 may be partially etched through an etching process and may be exposed to the outside. An upper portion of the landing pad LP may be shifted from the storage node contact BC in the first direction D1.

In some embodiments, the etching process on the landing pad layer may be performed to expose the second spacer 364. The second spacer 364 may be further etched through the exposed portion of the second spacer 364, and in this case, a final structure of the second spacer 364 may include an air gap. However, the present disclosure is not limited to this example.

Thereafter, the filler pattern 440 may be formed to cover or overlap exposed surfaces of the resulting structure and to enclose each of the landing pads LP, and the data storage patterns DSP may be formed on the landing pads LP, respectively.

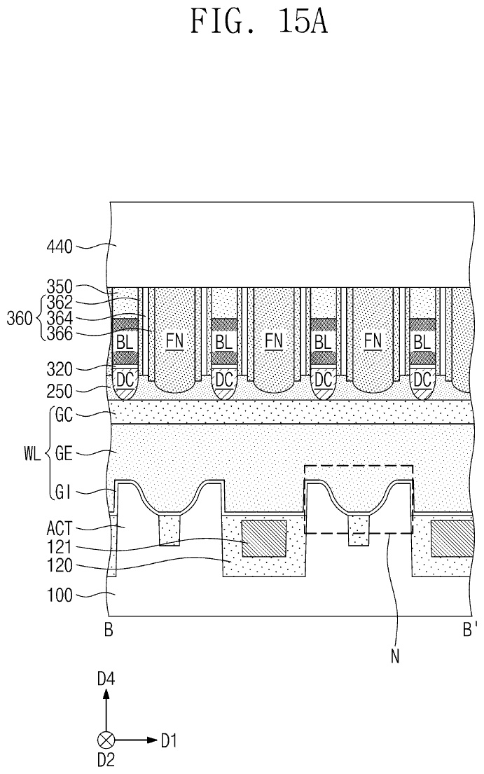

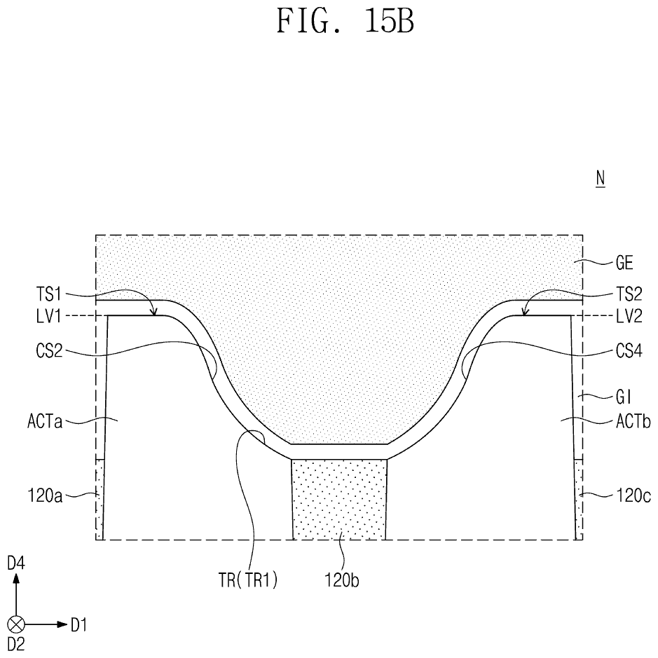

FIG. 15A is a sectional view illustrating a semiconductor memory device according to embodiments of the present disclosure, taken along a line B-B′ of FIG. 2. FIG. 15B is an enlarged sectional view illustrating a portion ‘N’ of FIG. 15A. For concise description, an element previously described with reference to FIGS. 3A to 4 may be identified by the same reference number without repeating an overlapping description thereof.

Referring to FIGS. 15A and 15B, the top surface TS1 of the first active pattern ACTa and the top surface of the second active pattern ACTb may extend in the first direction D1. A center line of the top surface TS1 of the first active pattern ACTa may be closer to the first device isolation pattern 120a than to the second device isolation pattern 120b. A center line of the top surface TS2 of the second active pattern ACTb may be closer to the third device isolation pattern 120c than to the second device isolation pattern 120b. The largest distance between the first and second active patterns ACTa and ACTb of FIG. 15B may be smaller than the smallest distance between the first and second active patterns ACTa and ACTb of FIG. 4 in the first direction D1.

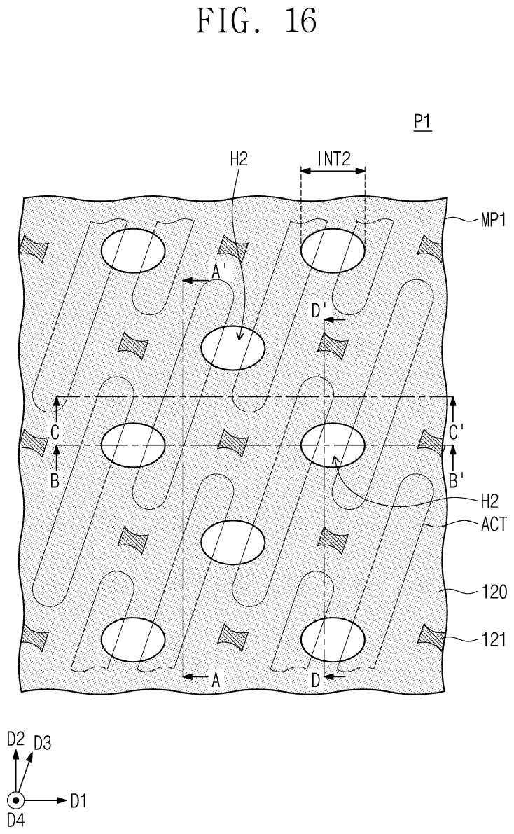

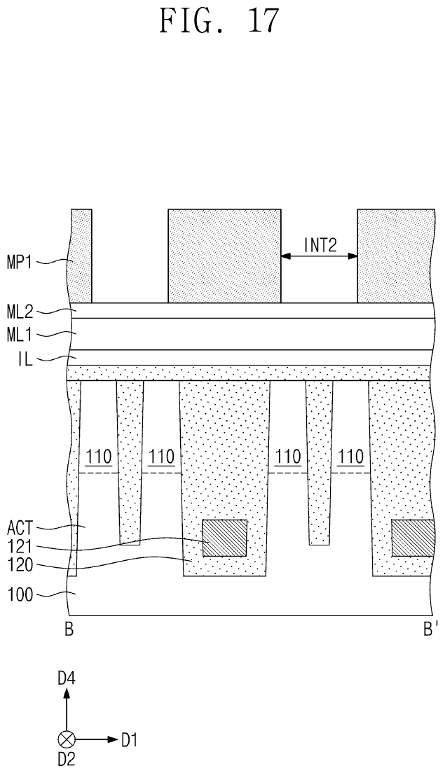

FIGS. 16 to 18 are sectional views illustrating a method of fabricating a semiconductor memory device according to embodiments of the present disclosure. FIG. 17 is a sectional view taken along a line B-B′ of FIG. 16. The semiconductor memory device previously described with reference to FIGS. 15A and 15B will be described in more detail with reference to FIGS. 16 to 18. For concise description, an element previously described with reference to FIGS. 5 to 14B may be identified by the same reference number without repeating an overlapping description thereof.

Referring to FIGS. 16 and 17, the first mask pattern MP1 may be formed on the substrate 100. The first mask pattern MP1 of FIG. 16 may have an area that is larger than the first mask pattern MP1 of FIG. 5. The first mask patterns MP1, which are adjacent to each other, may be spaced apart from each other in the first direction D1 by a second distance INT2 in the first direction D1.

A second hole H2 may be formed to expose the second mold layer ML2. The second hole H2 may have an elliptical shape, when viewed in a plan view. A length of a long axis of the second hole H2 may be equal to the second distance INT2. An area of the second hole H2 may be smaller than an area of the first hole H1. The first distance INT1 of FIG. 5 may be larger than the second distance INT2.

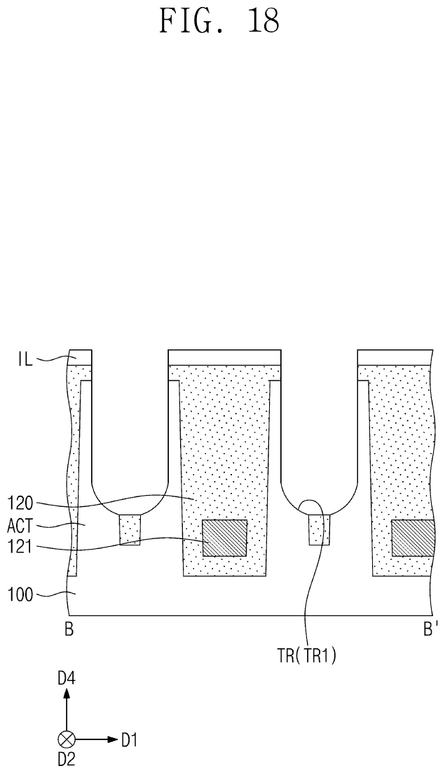

Referring to FIG. 18, the first and second mold layers ML1 and ML2 may be etched using the first mask pattern MP1 as an etch mask. Thereafter, the first mask pattern MP1 may be removed. The insulating layer IL, an upper portion of the device isolation pattern 120, and portions of the active patterns ACT may be etched using the first and second mold layers ML1 and ML2 as an etch mask. The upper portions of the active patterns ACT may not be fully etched, unlike the structure of FIG. 7A. The first trench region TR1 may be formed by the etching process. A width of the first trench region TR1 of FIG. 18 may be smaller than a width of the first trench region TR1 of FIG. 7A in the first direction D1.

Subsequent steps may be performed in the same manner to those in the method described with reference to FIGS. 11A and 11B. Since the second trench region TR2 is formed, remaining upper portions of the active patterns ACT may be etched to form the first and second active patterns ACTa and ACTb of FIG. 15B.

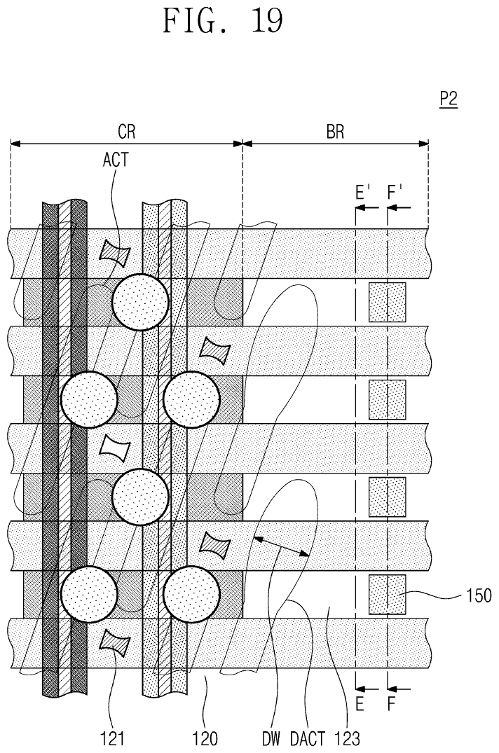

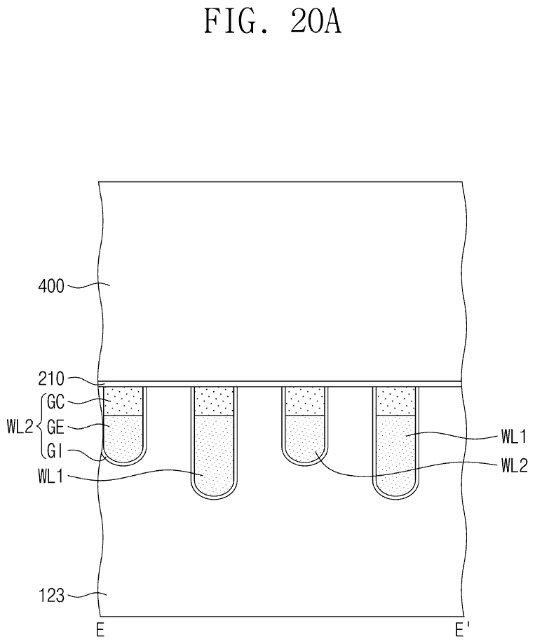

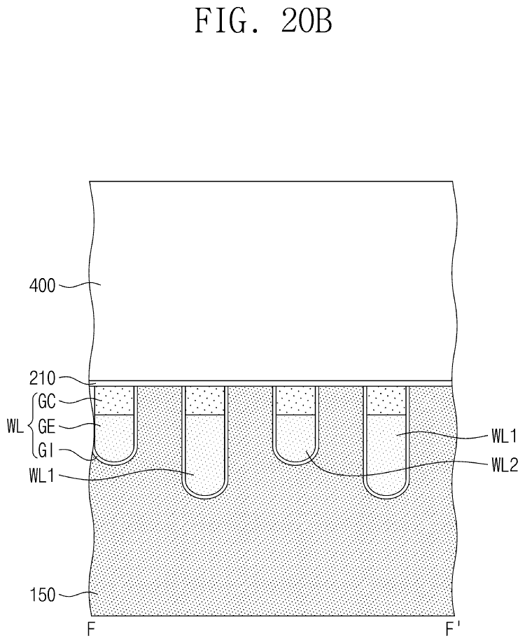

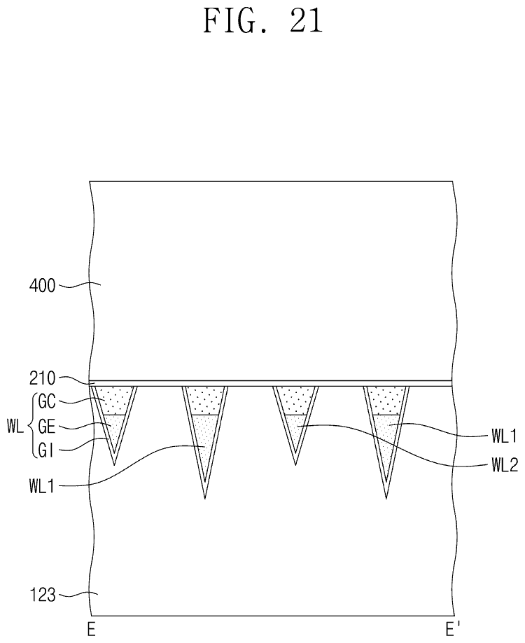

FIG. 19 is a plan view illustrating a portion (e.g., ‘P2’ of FIG. 1) of a semiconductor memory device according to embodiments of the present disclosure. FIGS. 20A to 20B are sectional views, which are taken along lines E-E′ and F-F′, respectively, of FIG. 19. FIG. 21 is a sectional view illustrating a method of fabricating a semiconductor memory device according to embodiments of the present disclosure, taken along a line E-E′ of FIG. 19. For concise description, an element previously described with reference to FIGS. 3A to 4 may be identified by the same reference number without repeating an overlapping description thereof.

Referring to FIG. 19, a boundary region BR, which is adjacent to cell regions CR of the cell blocks CB, may be provided on the substrate 100. The boundary region BR may be an edge portion of the cell block CB. The active patterns ACT previously described with reference to FIGS. 2 to 3D may be provided on the cell region CR. Boundary active patterns DACT and a boundary insulating pattern 123 may be formed on the boundary region BR. The boundary insulating pattern 123 may be formed of or include at least one of insulating materials (e.g., silicon oxide, silicon nitride, or combinations thereof).

The boundary active patterns DACT may be some of the active patterns ACT, which are provided in the outermost edge portion of the cell region CR. The boundary active patterns DACT may have a mean width that is larger than the active patterns ACT. The largest width DW of the boundary active patterns DACT may be larger than the largest width of the active patterns ACT. Portions of the boundary active patterns DACT may be located on the cell region CR, and other portions may be located on the boundary region BR. A width of the boundary active pattern DACT may be larger on the boundary region BR than on the cell region CR.

The word lines WL on the cell region CR may extend to or are on the boundary region BR. A nitride pattern 150 may be formed in a portion of the boundary region BR. The nitride pattern 150 may extend to cross or intersect the word lines WL. The nitride pattern 150 may be formed of or include silicon nitride, but the present disclosure is not limited to this example.

Referring to FIGS. 20A and 20B, the word lines WL, which are adjacent to each other in the second direction D2, may have different lengths from each other. Referring to FIG. 20A, the word lines WL may be provided on the boundary insulating pattern 123. The word lines WL on the boundary region BR may include first word lines WL1 and second word lines WL2. The first word lines WL1 and the second word lines WL2 may be alternatingly arranged.

The first word lines WL1 may correspond to word lines, which are formed in the first trench regions TR1 of FIG. 7B. The second word lines WL2 may correspond to word lines, which are formed in the second trench regions TR2 of FIG. 11B. A level of the bottom surfaces of the first word lines WL1 may be lower than a level of the bottom surfaces of the second word lines WL2 relative to the bottom surface of the substrate 100 in the fourth direction D4.

FIG. 20B may be substantially the same as FIG. 20A. However, the first and second word lines WL1 and WL2 may be provided on the nitride pattern 150. Referring to FIG. 21, the first and second word lines WL1 and WL2 may have a triangular section. The width of the first and second word lines WL1 and WL2 may increase as a distance from the bottom surface of the substrate 100 increases in the vertical direction D4.

Referring back to FIGS. 20A, 20B, and 21, the buffer pattern 210 and an interlayer insulating layer 400 may be sequentially formed on the first and second word lines WL1 and WL2, but the present disclosure is not limited to this example. The interlayer insulating layer 400 may include an insulating material.

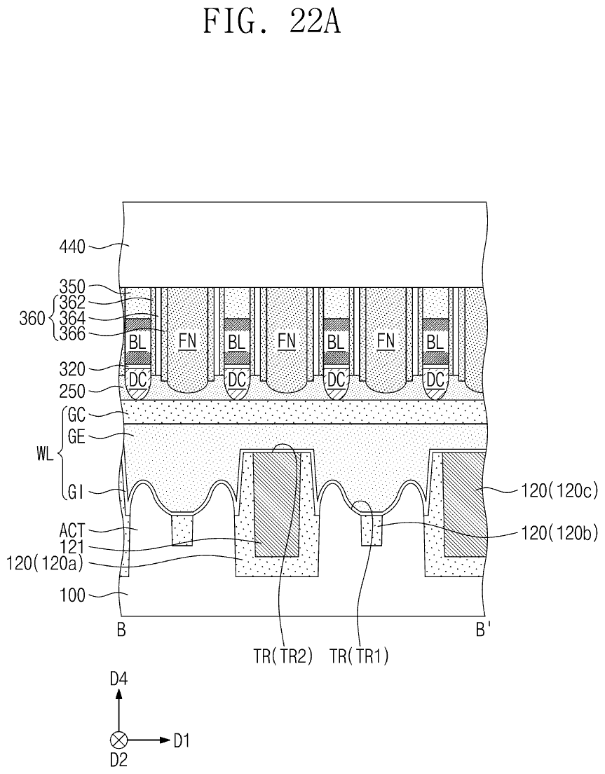

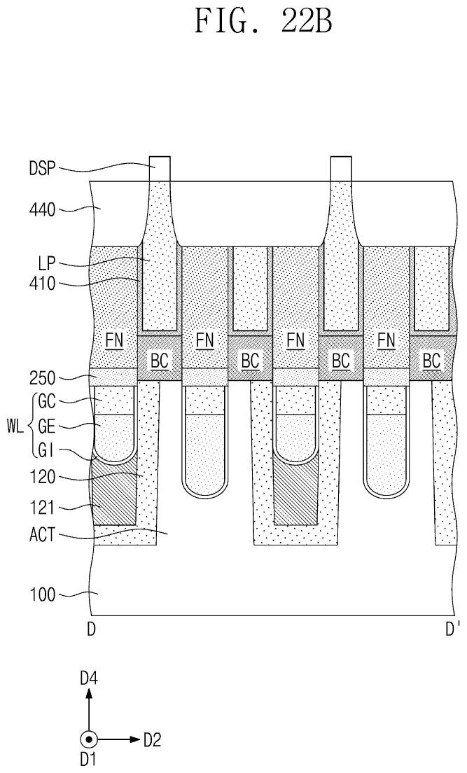

FIGS. 22A and 22B are sectional views illustrating a semiconductor memory device according to embodiments of the present disclosure. FIG. 22A is a sectional view taken along a line B-B′ of FIG. 2. FIG. 22B is a sectional view taken along a line D-D′ of FIG. 2. For concise description, an element previously described with reference to FIGS. 3B to 3D may be identified by the same reference number without repeating an overlapping description thereof.

Referring to FIGS. 22A and 22B, the top surface of the gapfill pattern 121 may be located at a level higher than the top surface of the second device isolation pattern 120b relative to the bottom surface of the substrate 100 in the fourth direction D4. The top surface of the gapfill pattern 121 may be substantially coplanar with the top surfaces of the first and third device isolation patterns 120a and 120c. In some embodiments, the level of the top surface of the gapfill pattern 121 may be lower than the level of the top surfaces of the first and third device isolation patterns 120a and 120c and may be higher than the level of the top surface of the second device isolation pattern 120b relative to the bottom surface of the substrate 100 in the fourth direction D4.

The gapfill pattern 121 may be in direct contact with the gate insulating pattern GI. A width of the gapfill pattern 121 may increase as a distance from the bottom surface of the substrate 100 increases in the vertical direction D4.

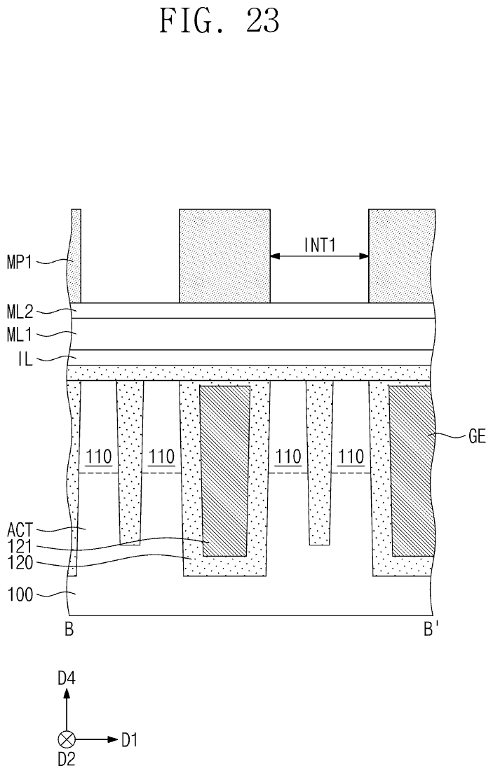

FIGS. 23, 24A, 24B, and 25 are sectional view illustrating a method of fabricating a semiconductor memory device, according to embodiments of the present disclosure. In detail, FIGS. 23, 24A, 24B, and 25 are sectional views corresponding to the line B-B′ of FIG. 2.

Hereinafter, the fabrication method of FIGS. 22A and 22B will be described in more detail with reference to FIGS. 23 to 25. For concise description, a previously-described element may be identified by the same reference number without repeating an overlapping description thereof.

FIG. 23 may be a sectional view corresponding to FIG. 6B. Referring to FIG. 23, a height of the gapfill pattern 121 of FIG. 23 may be larger than a height of the gapfill pattern 121 of FIG. 6B. A width of the gapfill pattern 121 may increase as a distance from the bottom surface of the substrate 100 increases in the vertical direction D4.

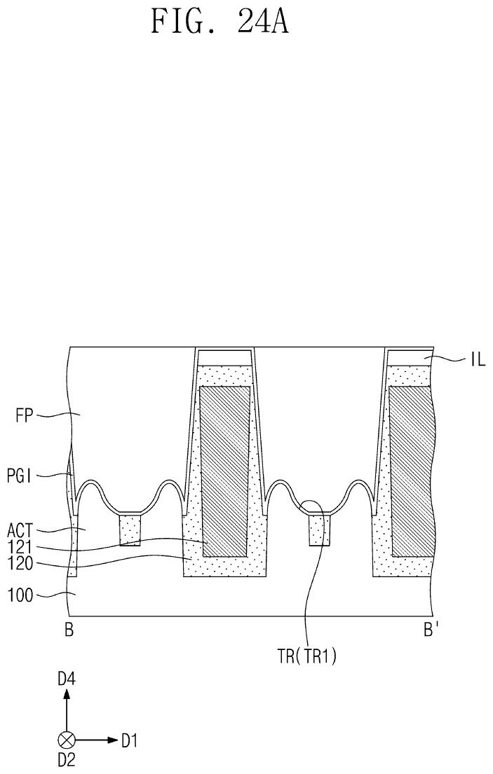

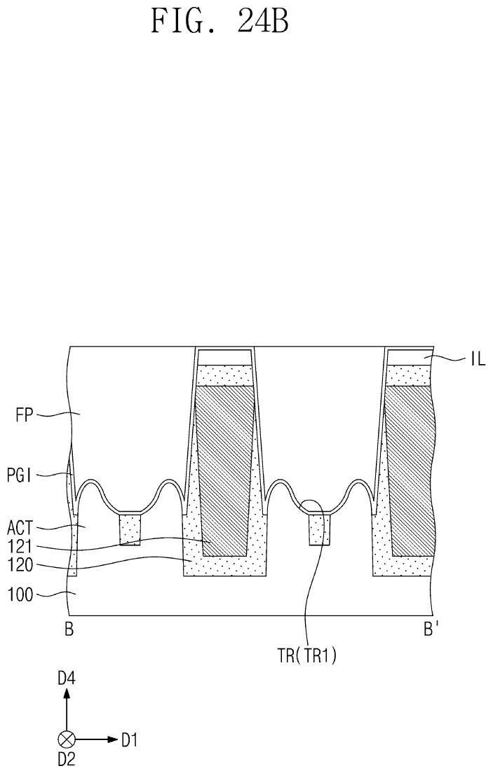

FIGS. 24A and 24B are sectional views corresponding to FIG. 8A. Referring to FIG. 24A, a level of the top surface of the gapfill pattern 121 may be higher than a level of the bottom surface of the first trench region TR1 relative to the bottom surface of the substrate 100 in the fourth direction D4. The level of the top surface of the gapfill pattern 121 may be higher than the highest level of the upper portion of the active patterns ACT etched relative to the bottom surface of the substrate 100 in the fourth direction D4.

FIG. 24B is a sectional view illustrating a modified embodiment of FIG. 24A.

Referring to FIG. 24B, an upper portion of the gapfill pattern 121 may be in direct contact with the first preliminary gate insulating layer PGI. This is because the upper portion of the gapfill pattern 121 is partially etched when the first trench region TR1 is formed by an etching process.

As a vertical height from the bottom surface of the substrate 100 increases in the vertical direction D4, a width of the gapfill pattern 121 may increase, reach a maximum value, and then decrease. In some embodiments, a portion of the gapfill pattern 121, which is in contact with the first preliminary gate insulating layer PGI, may have a decreasing width.

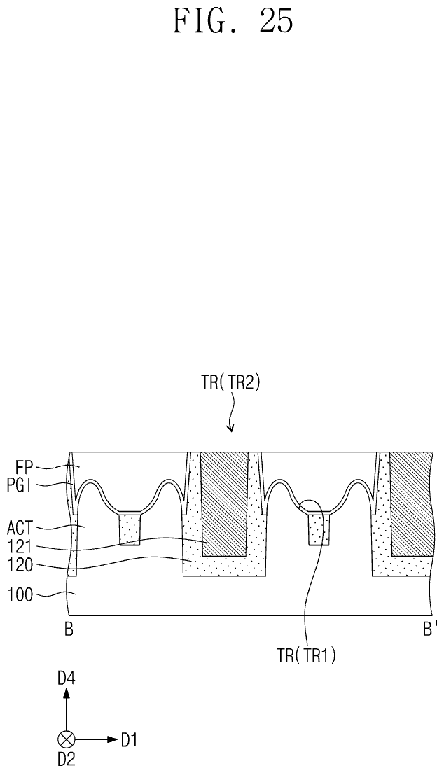

FIG. 25 is a sectional view corresponding to FIG. 11A. Referring to FIG. 25, an upper portion of the gapfill pattern 121 may be etched when the second trench region TR2 is formed. In this case, the top surface of the gapfill pattern 121 may be coplanar with the top surface of the capping pattern FP. The top surface of the gapfill pattern 121 may be coplanar with the top surface of the device isolation pattern 120.

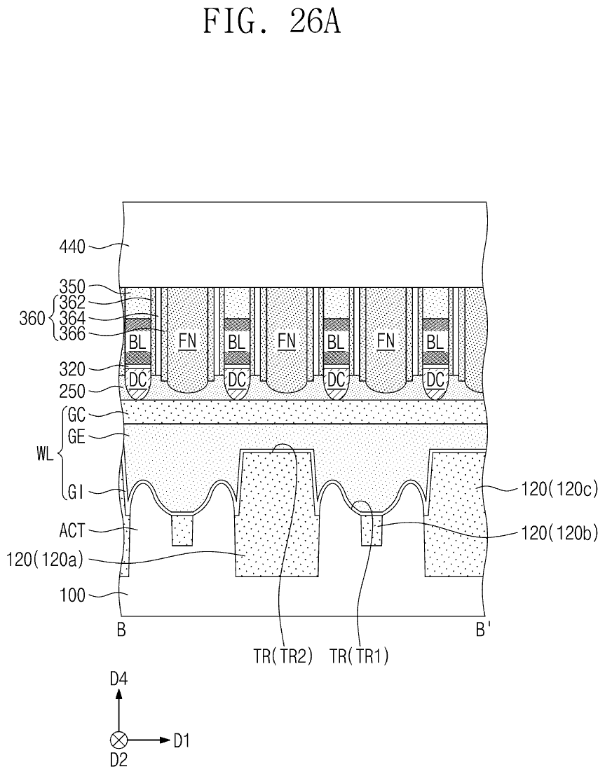

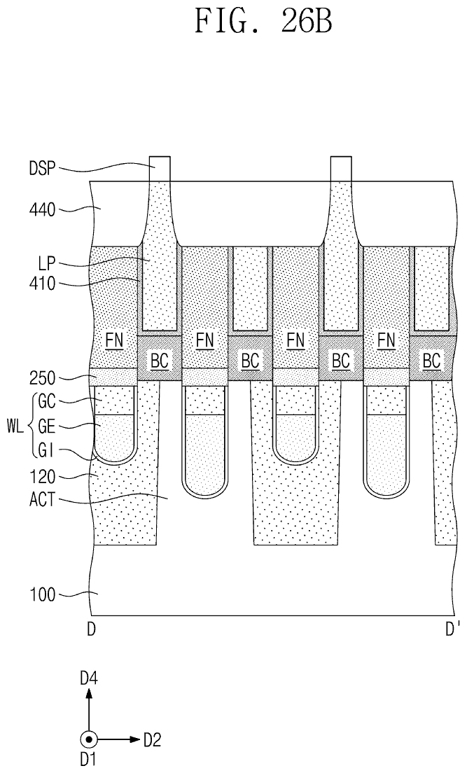

FIGS. 26A and 26B are sectional views illustrating a semiconductor memory device according to embodiments of the present disclosure. FIG. 26A is a sectional view taken along a line B-B′ of FIG. 2. FIG. 26B is a sectional view taken along a line D-D′ of FIG. 2. Referring to FIGS. 26A and 26B, the gapfill pattern 121 may be omitted from the first and third device isolation patterns 120a and 120c.

According to embodiments of the present disclosure, by increasing a distance between active patterns, a gate electrode may be provided over a wider region. For this, a hole patterning process may be additionally performed before a line patterning process. As a result of the hole patterning process, the active patterns may have an asymmetric structure. In this case, it may be possible to simultaneously improve the electrical and reliability characteristics of the semiconductor memory device.

While example embodiments of the present disclosure have been particularly shown and described, it will be understood by one of ordinary skill in the art that variations in form and detail may be made therein without departing from the scope of the attached claims.

What is claimed is:

1. A semiconductor memory device, comprising:
a substrate;
a first device isolation pattern and a second device isolation pattern having different widths from each other in a first direction that is parallel to a bottom surface of the substrate;
a first active pattern between the first device isolation pattern and the second device isolation pattern; and
a word line that extends in the first direction and is on the first active pattern,
wherein a first line extends in a second direction that is perpendicular to the bottom surface of the substrate,
wherein the first line intersects an uppermost portion of the first active pattern,
wherein the first line is spaced apart from the first device isolation pattern in the first direction by a first distance,
wherein the first line is spaced apart from the second device isolation pattern in the first direction by a second distance, and
wherein the first distance is less than the second distance.

2. The semiconductor memory device of claim 1, wherein:
the first active pattern comprises a first side surface and a second side surface,
the first side surface is adjacent to the first device isolation pattern,
the second side surface is adjacent to the second device isolation pattern, and
an absolute value of a mean slope of the first side surface is greater than an absolute value of a mean slope of the second side surface.

3. The semiconductor memory device of claim 2, wherein a length of the first side surface in the second direction is less than a length of the second side surface in the second direction.

4. The semiconductor memory device of claim 1, wherein:
the first device isolation pattern further comprises a gapfill pattern, and
the gapfill pattern comprises a nitride material.

5. The semiconductor memory device of claim 4, wherein the second device isolation pattern does not comprise the gapfill pattern.

6. The semiconductor memory device of claim 1, wherein a height of the first device isolation pattern relative to the bottom surface of the substrate in the second direction is greater than the a height of the second device isolation pattern relative to the bottom surface of the substrate in the second direction.

7. The semiconductor memory device of claim 1, wherein a height of the first active pattern relative to the bottom surface of the substrate in the second direction is less than a height of the first device isolation pattern relative to the bottom surface of the substrate in the second direction.

8. The semiconductor memory device of claim 1, wherein a distance between the uppermost portion of the first active pattern and the first device isolation pattern in the first direction is less than a distance between the uppermost portion of the first active pattern and the second device isolation pattern in the first direction.

9. The semiconductor memory device of claim 1, further comprising a second active pattern adjacent to the first active pattern in the first direction, wherein:
the second active pattern is between the second device isolation pattern and a third device isolation pattern,
a second line extends in the second direction and intersects an uppermost portion of the second active pattern,
the second line is spaced apart from the third device isolation pattern in the first direction by a third distance,
the second line is spaced apart from the second device isolation pattern in the first direction by a fourth distance, and
the third distance is less than the fourth distance.

10. The semiconductor memory device of claim 1, wherein:
the first active pattern comprises a first body portion and a first protruding portion on the first body portion, and
the first line is offset from a center line of the first body portion in the first direction.

11. A semiconductor memory device, comprising:
a substrate comprising a first active pattern;
a first device isolation pattern and a second device isolation pattern having different widths from each other in a first direction that is parallel to a bottom surface of the substrate, wherein the first active pattern is on the substrate and between the first device isolation pattern and the second device isolation pattern; and
a word line that extends in the first direction and is on the first active pattern,
wherein the first active pattern comprises a first side surface and a second side surface,
wherein the first side surface is adjacent to the first device isolation pattern,
wherein the second side surface is adjacent to the second device isolation pattern, and
wherein an absolute value of a mean slope of the first side surface is greater than an absolute value of a mean slope of the second side surface.

12. The semiconductor memory device of claim 11, wherein:
the first device isolation pattern further comprises a gapfill pattern, and
the gapfill pattern comprises a nitride material.

13. The semiconductor memory device of claim 11, wherein a length of the first side surface in a second direction that is perpendicular to the bottom surface of the substrate is less than a length of the second side surface in the second direction.

14. The semiconductor memory device of claim 11, wherein a height of the first device isolation pattern relative to the bottom surface of the substrate in a second direction that is perpendicular to the bottom surface of the substrate is greater than a height of the second device isolation pattern relative to the bottom surface of the substrate in the second direction.

15. The semiconductor memory device of claim 11, wherein a height of the first active pattern relative to the bottom surface of the substrate in a second direction that is perpendicular to the bottom surface of the substrate is less than a height of the first device isolation pattern relative to the bottom surface of the substrate in the second direction.

16. A semiconductor memory device, comprising:
a substrate that comprises a cell region and a boundary region;
active patterns on the cell region of the substrate, wherein the active patterns comprise a first active pattern and a second active pattern that are adjacent to each other,
a first device isolation pattern and a second device isolation pattern that are on the substrate and have different widths from each other in a first direction that is parallel to a bottom surface of the substrate, wherein the first active pattern is between the first device isolation pattern and the second device isolation pattern;
word lines that extend in the first direction and are on the first active pattern;
bit lines that intersect the word lines and are on the substrate;
bit line capping patterns that are respectively on the bit lines;
storage node contacts between adjacent ones of the bit lines;
landing pads that are respectively on the bit line capping patterns and the storage node contacts and are electrically connected to respective ones of the storage node contacts; and
a capacitor that is on and electrically connected to one of the landing pads,
wherein a distance between an uppermost portion of the first active pattern and the first device isolation pattern in the first direction is less than a distance between the uppermost portion of the first active pattern and second device isolation pattern in the first direction.

17. The semiconductor memory device of claim 16, further comprising a boundary active pattern and a boundary insulating pattern that are on the boundary region, wherein:
the word lines are on the boundary region,
the word lines comprise a first word line and a second word line that are adjacent to each other, and
a height of a bottom surface of the first word line relative to the bottom surface of the substrate in a second direction that is perpendicular to the bottom surface of the substrate is less than a height of a bottom surface of the second word line relative to the bottom surface of the substrate in the second direction.

18. The semiconductor memory device of claim 17, wherein:
the height of the bottom surface of the first word line relative to the bottom surface of the substrate in the second direction is equal to a height of a top surface of the second device isolation pattern relative to the bottom surface of the substrate in the second direction, and
the height of the bottom surface of the second word line relative to the bottom surface of the substrate in the second direction is equal to a height of a top surface of the first device isolation pattern relative to the bottom surface of the substrate in the second direction.

19. The semiconductor memory device of claim 16, wherein a height of the uppermost portion of the first active pattern relative to the bottom surface of the substrate in a second direction that is perpendicular to the bottom surface of the substrate is less than a height of an uppermost portion of the first device isolation pattern relative to the bottom surface of the substrate in the second direction.

20. The semiconductor memory device of claim 16, wherein:
the first active pattern comprises a first side surface and a second side surface,
the first side surface is adjacent to the first device isolation pattern,
the second side surface is adjacent to the second device isolation pattern, and
a length of the first side surface in a second direction that is perpendicular to the bottom surface of the substrate is less than a length of the second side surface in the second direction.
